(19) United States
(12) Patent Application Publication
(10) Pub. No.: US 2026/0204205 A1
(43) Pub. Date: Jul. 16, 2026

(54) DISPLAY DEVICE AND ELECTRONIC DEVICE INCLUDING THE SAME

(71) Applicant: Samsung Display Co., Ltd., Yongin-si (KR)

(72) Inventors: Ji Sun KIM, Yongin-si (KR); Kwi Hyun KIM, Yongin-si (KR); Sun Hwa LEE, Yongin-si (KR); Se Hyun LEE, Yongin-si (KR); Kyung Hoon CHUNG, Yongin-si (KR)

(21) Appl. No.: 19/386,056

(22) Filed: Nov. 11, 2025

(30) Foreign Application Priority Data
Jan. 14, 2025 (KR) 10-2025-0005738

(51) Int. Cl. G09G 3/32; G09G 3/3266

(52) U.S. Cl. CPC G09G 3/32; G09G 3/3266; G09G 2310/0216; G09G 2310/0267; G09G 2330/021

(57) ABSTRACT

A display device includes: a display panel including a display area, a non-display area, and pixels in the display area; a light emitting driving portion to apply light emitting control signals to the pixels, and located in the non-display area on a first side of the display area; and a scan driving portion configured to apply scan signals to the display panel, and located in the non-display area on a second side opposite to the first side. The pixels include: a first sub-pixel to emit light of a first wavelength; and a second sub-pixel to emit light of a second wavelength shorter than the first wavelength. he light emitting driving portion includes: a first light emitting driver to apply a first light emitting control signal to the first sub-pixel; and a second light emitting driver to apply a second light emitting control signal to the second sub-pixel.

### CROSS-REFERENCE TO RELATED APPLICATION

The present application claims priority to and the benefit of Korean Patent Application No. 10-2025-0005738, filed on January 14, 2025, in the Korean Intellectual Property Office, the entire disclosure of which is incorporated by reference herein.

### BACKGROUND

### 1. Field

Aspects of embodiments of the present disclosure relate to a display device, and an electronic device including the display device.

### 2. Description of the Related Art

As information society develops, the demand for display devices for displaying images is increasing in various forms. For example, display devices are being included in various electronic devices, and used as display screens of the electronic devices. As such, various kinds of display devices, such as light-emitting display devices, are being developed.

### SUMMARY

Embodiments of the present disclosure may be directed to a display device having a symmetrical non-display area, and an electronic device including the display device.

However, the present disclosure is not limited to the aspects and features above. The above and additional aspects and features will be set forth, in part, in the description that follows, and in part, may be apparent from the description, or may be learned by practicing one or more of the presented embodiments of the present disclosure.

According to one or more embodiments of the present disclosure, a display device includes: a display panel including a display area, a non-display area, and a plurality of pixels in the display area; a light emitting driving portion configured to apply light emitting control signals to the plurality of pixels, and located in the non-display area on a first side of the display area; and a scan driving portion configured to apply scan signals to the display panel, and located in the non-display area on a second side opposite to the first side of the display area. The plurality of pixels includes: a first sub-pixel configured to emit light of a first wavelength; and a second sub-pixel configured to emit light of a second wavelength shorter than the first wavelength. The light emitting driving portion includes: a first light emitting driver configured to apply a first light emitting control signal to the first sub-pixel; and a second light emitting driver configured to apply a second light emitting control signal to the second sub-pixel.

In an embodiment, the scan driving portion may include a write scan signal driver, an initialization scan signal and control scan signal driver, and a bias scan signal driver, each connected to a sub-pixel from among the first and second sub-pixels, and configured to apply a scan signal.

In an embodiment, the non-display area may surround around the display area, and the first side and the second side may have a symmetrical shape with each other.

In an embodiment, the write scan signal driver, the initialization scan signal and control scan signal driver, and the bias scan signal driver may be located in order of a decreasing size closer to the display area.

In an embodiment, the write scan signal driver, the initialization scan signal and control scan signal driver, and the bias scan signal driver may be located in order closer to the display area.

In an embodiment, the light emitting driver and the scan driver may be symmetrical with each other about the display area.

In an embodiment, the display device may further include: a first light emitting control line connecting the first light emitting driver and the first sub-pixel to each other; and a second light emitting control line connecting the second light emitting driver and the second sub-pixel to each other.

In an embodiment, the display device may further include: a write scan line connecting the write scan signal driver to the first sub-pixel and the second sub-pixel; a control scan line connecting the initialization scan signal and control scan signal driver to the first sub-pixel and the second sub-pixel; an initialization scan line connecting the initialization scan signal and control scan signal driver to the first sub-pixel and the second sub-pixel; and a bias scan line connecting the bias scan signal driver to the first sub-pixel and the second sub-pixel.

In an embodiment, the plurality of pixels may further include a third sub-pixel configured to emit light of a third wavelength shorter than the light of the first wavelength, and the second light emitting driver may be configured to apply the second light emitting control signal to the third sub-pixel.

In an embodiment, the second light emitting control line may further connect the second light emitting driver and the third sub-pixel to each other, the write scan line may further connect the write scan signal driver and the third sub-pixel to each other, the control scan line may further connect the initialization scan signal and control scan signal driver and the third sub-pixel to each other, the initialization scan line may further connect the initialization scan signal and control scan signal driver and the third sub-pixel to each other, and the bias scan line may further connect the bias scan signal driver and the third sub-pixel to each other.

In an embodiment, the display area may have a square or circular shape.

In an embodiment, the first sub-pixel may include a first pixel circuit, and a first light emitting element electrically connected to the first pixel circuit. The second sub-pixel may include a second pixel circuit, and a second light emitting element electrically connected to the second pixel circuit. The third sub-pixel may include a third pixel circuit, and a third light emitting element electrically connected to the third pixel circuit.

According to one or more embodiments of the present disclosure, a display device includes: a display panel including a display area, a non-display area, and a first sub-pixel and a second sub-pixel in the display area; a light emitting driving portion including a first light emitting driver configured to apply a first light emitting control signal to the first sub-pixel, and a second light emitting driver configured to apply a second light emitting control signal to the second sub-pixel; and a scan driving portion including a write scan signal driver, an initialization scan signal and control scan signal driver, and a bias scan signal driver, each connected to the first sub-pixel and the second sub-pixel, and configured to apply a scan signal. The light emitting driver and the scan driver are symmetrically located in the non-display area with the display panel therebetween.

In an embodiment, the write scan signal driver, the initialization scan signal and control scan signal driver, and the bias scan signal driver may be located in order closer to the display area.

In an embodiment, the display device may further include: a first light emitting control line connecting the first light emitting driver and the first sub-pixel to each other; and a second light emitting control line connecting the second light emitting driver and the second sub-pixel to each other.

In an embodiment, the display device may further include: a write scan line connecting the write scan signal driver to the first sub-pixel and the second sub-pixel; a control scan line connecting the initialization scan signal and control scan signal driver to the first sub-pixel and the second sub-pixel; an initialization scan line connecting the initialization scan signal and control scan signal driver to the first sub-pixel and the second sub-pixel; and a bias scan line connecting the bias scan signal driver to the first sub-pixel and the second sub-pixel.

In an embodiment, the first light emitting control line may extend in a first direction in the display area, and may be electrically connected to the first sub-pixel. The second light emitting control line may extend in the first direction in the display area, and may be electrically connected to the second sub-pixel.

In an embodiment, the first sub-pixel may include a first light emitting element configured to emit light of a first wavelength, and the second sub-pixel may include a second light emitting element configured to emit light of a second wavelength shorter than the first wavelength.

According to one or more embodiments of the present disclosure, an electronic device includes: a display device; a window on the display device; and a bottom cover under the display device. The display device includes: a display panel including a display area, a non-display area, and a plurality of pixels in the display area; a light emitting driving portion configured to output light emitting control signals to the display panel, and located in the non-display area on a second side opposite to a first side of the display area; and a scan driving portion configured to output scan signals to the display panel, and located in the non-display area on the first side of the display area. The plurality of pixels includes a first sub-pixel configured to emit light of a first wavelength, and a second sub-pixel configured to emit light of a second wavelength shorter than the first wavelength. The light emitting driving portion includes a first light emitting driver configured to apply a first light emitting control signal to the first sub-pixel, and a second light emitting driver configured to apply a second light emitting control signal to the second sub-pixel.

In an embodiment, the electronic device may further include: a battery located in a space of the bottom cover, and configured to supply power to the display device; and a middle frame between the window and the bottom cover.

According to some embodiments of the present disclosure, in a display device and an electronic device including the display device, a first light emitting driver connected to a first sub-pixel and a second light emitting driver connected to a second sub-pixel may be arranged on a first side of a non-display area, and a plurality of scan drivers may be arranged on a second side of the non-display area, so that the first side and the second side of the non-display area may be symmetrically formed with each other.

According to some embodiments of the present disclosure, in the display device and the electronic device including the display device, a wiring resistance may be reduced by arranging a small-sized driver close to the display area.

However, the present disclosure is not limited to the above aspects and features, and the above and additional aspects and features will be set forth, in part, in the detailed description that follows with reference to the drawings, and in part, may be apparent therefrom, or may be learned by practicing one or more of the presented embodiments of the present disclosure.

### BRIEF DESCRIPTION OF THE DRAWINGS

The above and other aspects and features of the present disclosure will be more clearly understood from the following detailed description of the illustrative, non-limiting embodiments with reference to the accompanying drawings.

FIG. 1 is a perspective view illustrating a display device according to an embodiment.

FIG. 2 is a plan view illustrating a display panel according to an embodiment.

FIG. 3 is a block diagram illustrating a display device according to an embodiment.

FIG. 4 is a graph illustrating an external quantum efficiency and current density sections of a sub-pixel according to an embodiment.

FIG. 5 is an equivalent circuit diagram illustrating a light emitting control signal and a sub-pixel according to an embodiment.

FIG. 6 is a waveform diagram illustrating driving signals of a sub-pixel according to an embodiment.

FIG. 7 is an enlarged view of the areas A and B of FIG. 2 according to an embodiment.

FIG. 8 is an enlarged view of the areas A and B of FIG. 2 according to an embodiment.

FIG. 9 is an enlarged view of the areas A and B of FIG. 2 according to an embodiment.

FIG. 10 is a plan view illustrating a display panel according to an embodiment.

FIG. 11 is an enlarged view of the areas A’, B’, C’, and D’ of FIG. 10 according to an embodiment.

FIG. 12 is an enlarged view of the areas A’, B’, C’, and D’ of FIG. 10 according to an embodiment.

FIG. 13 is a layout diagram illustrating a light emitting element layer of a display panel according to an embodiment.

FIG. 14 is a cross-sectional view illustrating an example of a cross-section of a display panel corresponding to the line X1-X1’ of FIG. 13.

FIG. 15 is a cross-sectional view illustrating the area A2 of FIG. 14 in more detail.

FIG. 16 is a cross-sectional view illustrating an example of a cross-section of a display panel corresponding to the line X2-X2’ and the line X3-X3’ of FIG. 13.

FIG. 17 is a cross-sectional view illustrating an example of a cross-section of a display panel corresponding to the line X1-X1’ of FIG. 13.

FIGS. 18 and 19 illustrate a smart watch including a display device according to some embodiments.

FIG. 20 is an exploded perspective view of a smart watch including a display device according to an embodiment.

FIG. 21 illustrates a virtual reality device including a display device according to an embodiment.

FIG. 22 illustrates a head-mounted display device including a display device according to an embodiment.

FIG. 23 illustrates an automobile instrument panel and center fascia including display devices according to an embodiment.

FIG. 24 illustrates a transparent display device including a display device according to an embodiment.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

Further, as would be understood by a person having ordinary skill in the art, in view of the present disclosure in its entirety, each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner, unless otherwise stated or implied.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature’s relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

Additionally, the use of cross-hatching and/or shading in the accompanying drawings is generally provided to illustrate boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, and the like of the elements, unless otherwise specified.

Further, it should be expected that the shapes shown in the figures may vary in practice depending, for example, on tolerances and/or manufacturing techniques. Accordingly, the embodiments of the present disclosure should not be construed as being limited to the specific shapes shown in the figures, and should be construed considering changes in shapes that may occur, for example, as a result of manufacturing. As such, the shapes shown in the drawings may not depict the actual shapes of areas of the device, and the present disclosure is not limited thereto.

For example, an implanted region illustrated as a rectangle may have rounded or curved features and/or a gradient of an implant concentration at its edges, rather than a binary change from an implanted region to a non-implanted region. Likewise, a buried region formed by implantation may result in some implantation in the region between the buried region and a surface through which the implantation takes place. Thus, the regions illustrated in the drawings are schematic in nature and their shapes are not intended to illustrate the actual shape of a region of a device, and thus, are not intended to be limiting. Additionally, as those having ordinary skill in the art would realize, the described embodiments may be modified in various different ways, all without departing from the spirit and/or scope of the present disclosure.

As used herein, the phrases “on a plane” and “in a plan view” may refer to a view of a target portion from the top, and the phrases “on a cross-section” and “in a cross-sectional view” may refer to a view of a cross-section formed by vertically cutting a target portion from the side.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being "electrically connected" to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” "includes," "including," "has," "have," and "having," when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression "A and/or B" denotes A, B, or A and B. Expressions such as “at least one of,” when preceding a list of elements, modify the entire list of elements and do not modify the individual elements of the list. For example, the expression "at least one of a, b, or c," “at least one of a, b, and c,” and “at least one selected from the group consisting of a, b, and c” indicates only a, only b, only c, both a and b, both a and c, both b and c, all of a, b, and c, or variations thereof.

As used herein, the term "substantially," "about," and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms "use," "using," and "used" may be considered synonymous with the terms "utilize," "utilizing," and "utilized," respectively.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein.

The electronic or electric devices and/or any other relevant devices or components according to one or more embodiments of the present disclosure described herein may be implemented utilizing any suitable hardware, firmware (e.g., an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate.

Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, and/or the like. Also, a person having ordinary skill in the art should recognize that the functionality of various computing devices may be combined or integrated into a single computing device, or the functionality of a particular computing device may be distributed across one or more other computing devices without departing from the spirit and scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

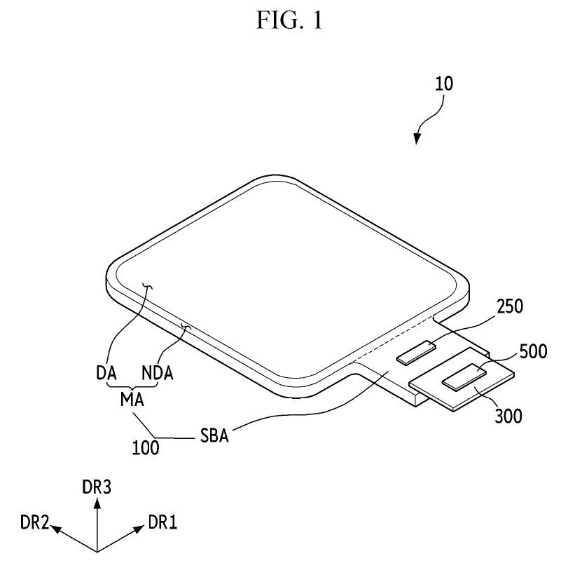

FIG. 1 is a perspective view illustrating a display device according to an embodiment.

Referring to FIG. 1, the display device 10 is a device for displaying a video or a still image, and may be a mobile phone, a smart phone, a tablet personal computer, or a portable electronic device, such as a smart watch, a watch phone, a mobile communication terminal, an electronic notebook, an e-book, a portable multimedia player (PMP), a navigation system, an ultra mobile PC (UMPC), or the like. The display device 10 may also be included in various kinds of electronic devices, such as televisions, laptops, monitors, billboards, Internet of Things (IOT) devices, and/or the like, and may be used as a display screen. Also, the display device 10 may be included in other suitable electronic devices, such as a virtual reality (VR) device or an augmented reality (AR) device, and may be used to display an image in the electronic devices. In an embodiment, an electronic device including the display device 10 may further include a display device storage portion in which the display device 10 is stored, and/or a case or a cover for protecting the display device 10.

In an embodiment, the display device 10 may be a light emitting display device, such as an organic light-emitting display device utilizing an organic light-emitting diode, a quantum dot light-emitting display device including a quantum dot light-emitting layer, an inorganic light-emitting display device including an inorganic semiconductor, and/or a miniaturized light-emitting display device utilizing a micro or nano light emitting diode (micro LED or nano LED). Hereinafter, for convenience of illustration, the display device 10 may be described in more detail in the context of a micro-light emitting display device, but the present disclosure is not limited thereto. Further, hereinafter, for convenience of illustration, an ultra-small light emitting diode may be described in more detail as a light emitting element.

The display device 10 includes a display panel 100, a display driving circuit 250, a circuit substrate 300, and a power supply circuit 500.

The display panel 100 may be formed as a rectangular shaped plane having a short side extending in the first direction DR1, and a long side extending in the second direction DR2 that crosses or intersects the first direction DR1. A corner where the short side extending in the first direction DR1 and the long side extending in the second direction DR2 meet each other may be rounded to have a suitable curvature (e.g., a predetermined curvature), or may be formed at a right angle. The planar shape of the display panel 100 is not limited to the rectangle, but may be formed in other suitable polygonal, circular, or oval shapes. The display panel 100 may be formed flat or substantially flat, but is not limited thereto. As an example, the display panel 100 may be formed at left and right ends, and may include curved portions with a constant curvature or a changing curvature. In addition, the display panel 100 may be flexibly formed to be bent, curved, bent, folded, or rolled.

The display panel 100 may include a main area MA and a sub-area SBA.

The main area MA may include a display area DA that displays an image, and a non-display area NDA that may be a surrounding area (e.g., around a periphery) of the display area DA. The display area DA may include a plurality of pixels that display an image. Each pixel may include a plurality of sub-pixels. For example, each of the pixels may include a first sub-pixel that emits light of a first color (e.g., a first light), a second sub-pixel that emits light of a second color (e.g., a second light), and a third sub-pixel that emits light of a third color (e.g., a third light), but the present disclosure is not limited thereto.

The sub-area SBA may protrude from one side of the main area MA in a second direction DR2 (e.g., in the longitudinal direction of the display panel 100). In FIG. 1, the sub-area SBA is illustrated as being unfolded, but the sub-area SBA may be bent, in which case it may be arranged on a bottom surface of the display panel 100. When the sub-area SBA is bent, it may overlap with the main area MA in a third direction DR3, which is the thickness direction of the display panel 100. The display driving circuit 250 may be arranged in the sub-area SBA.

The display driving circuit 250 may generate signals and voltages for driving the display panel 100. The display driving circuit 250 may be formed as an integrated circuit (IC), and may be attached to the display panel 100 using a chip on glass (COG) method, a chip on plastic (COP) method, or an ultrasonic bonding method, but the present disclosure is not limited thereto. In an embodiment, the display driving circuit 250 may be attached to the circuit substrate 300 using a chip on film (COF) method.

The circuit substrate 300 may be attached to one end of the sub-area SBA of the display panel 100. As such, the circuit substrate 300 may be electrically connected to the display panel 100 and the display driving circuit 250. The display panel 100 and the display driving circuit 250 may receive digital video data, timing signals, and driving voltages through the circuit substrate 300. The circuit substrate 300 may be a flexible film, such as a flexible printed circuit substrate, a printed circuit substrate, or a chip on film.

The power supply circuit 500 may generate a plurality of panel driving voltages according to an external power supply voltage. The power supply circuit 500 may be formed as an integrated circuit (IC), and may be attached to the circuit substrate 300 using a COF method.

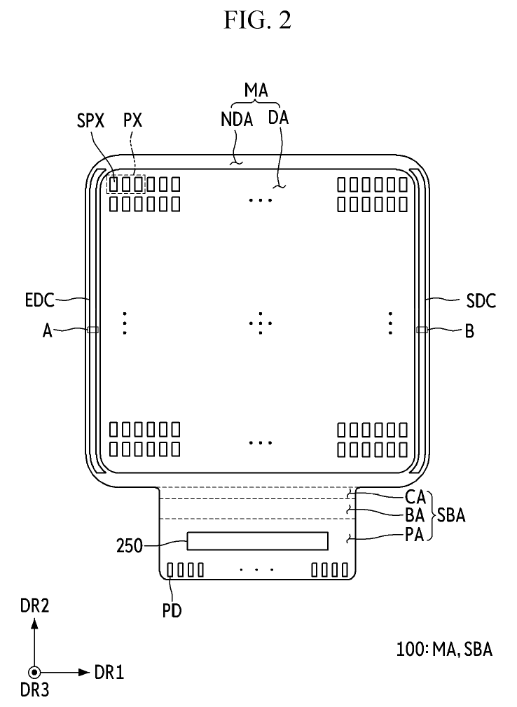

FIG. 2 is a plan view illustrating a display panel according to an embodiment. FIG. 2 illustrates that the sub-area SBA is unfolded without being bent.

Referring to FIGS. 1 and 2, the display panel 100 may include the main area MA and the sub-area SBA.

The main area MA may include the display area DA that displays an image, and the non-display area NDA that is a peripheral area of the display area DA. The display area DA may occupy most of the main area MA. The display area DA may be placed in the center of the main area MA.

The display area DA includes pixels PX for displaying an image, and each pixel PX may include a plurality of sub-pixels SPX. A pixel PX may be defined as a sub-pixel group that is the smallest unit capable of expressing a white gradation (e.g., a white grayscale level or value).

The non-display area NDA may be arranged to be adjacent to the display area DA. The non-display area NDA may be an area outside the display area DA. The non-display area NDA may be arranged to surround (e.g., around a periphery of) the display area DA. The non-display area NDA may be an edge area of the display panel 100.

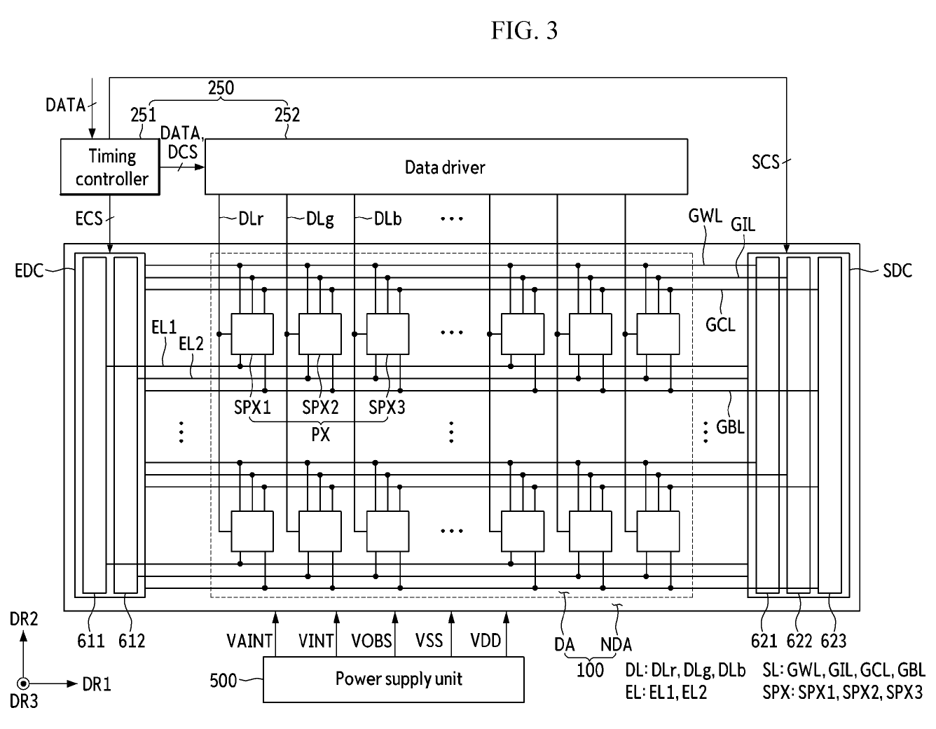

A light emitting driving portion EDC and a scan driving portion SDC may be arranged in the non-display area NDA. The light emitting driving portion EDC may be arranged on one side (e.g., the left side) of the display panel 100, and the scan driving portion SDC may be arranged on another side (e.g., the right side) of the display panel, but the present disclosure is not limited thereto. Each of the light emitting driving portion EDC and the scan driving portion SDC may be electrically connected to the display driving circuit 250 through scan fan out lines. The light emitting driving portion EDC may receive a driving control signal ECS from the display driving circuit 250. The scan driving portion SDC may receive a scan control signal from the display driving circuit 250, and may generate scan signals according to the scan control signal to output the scan signals to the scan lines. The configuration and the operation of the light emitting driving portion EDC and the scan driving portion SDC will be described in more detail below with reference to FIGS. 3 to 7.

The sub-area SBA may protrude from one side of the main area MA in the second direction DR2. The length of the sub-area SBA in the second direction DR2 may be smaller than the length of the main area MA in the second direction DR2. The length of the sub area SBA in the first direction DR1 may be less than the length of the main area MA in the first direction DR1, or may be equal to or substantially equal to the length of the main area MA in the first direction DR1. The sub-area SBA may be bent or curved and arranged below the main area MA. In this case, the sub-area SBA may overlap with the main area MA in the third direction DR3.

The sub-area SBA may include a connection area CA, a pad area PA, and a bending area BA.

The connection area CA may be an area protruding from one side of the main area MA in the second direction DR2. One side of the connection area CA may be in contact with the non-display area NDA of the main area MA, and another side of the connection area CA may be in contact with the bending area BA.

The pad area PA is an area where pads PD and the display driving circuit 250 are arranged. The display driving circuit 250 may be attached to driving pads of the pad area PA using a conductive adhesive member, such as an anisotropic conductive film. The circuit substrate 300 may be attached to the pads PD of the pad area PA using a conductive adhesive member, such as an anisotropic conductive film. One side of the pad area PA may be in contact with the bending area BA.

The bending area BA is an area that may be bent (e.g., a bent area). When the bending area BA is bent, the pad area PA may be arranged below (e.g., underneath) the connection area CA and below (e.g., underneath) the main area MA. The bending area BA may be arranged between the connection area CA and the pad area PA. One side of the bending area BA may be in contact with the connection area CA, and another side of the bending area BA may be in contact with the pad area PA.

FIG. 3 is a block diagram illustrating a display device according to an embodiment.

Referring to FIG. 3, the pixels PX may be arranged in the first direction DR1 and the second direction DR2. For example, the pixels PX may be arranged in a matrix form in the first direction DR1 and the second direction DR2. Scan lines SL, first light emitting control lines EL1, and second light emitting control lines EL2 may extend in the first direction DR1, and may be arranged or placed along the second direction DR2. Data lines DL may extend in the second direction DR2, and may be arranged or placed along the first direction DR1. The scan lines SL may include write scan lines GWL, initialization scan lines GIL, control scan lines GCL, and bias scan lines GBL. The configuration or the number of the scan lines SL may vary depending on the structure or a driving method of the pixels PX.

Each of the pixels PX may include a plurality of sub-pixels SPX. For example, each of the pixels PX may include a first sub-pixel SPX1, a second sub-pixel SPX2, and a third sub-pixel SPX3. The first sub-pixel SPX1, the second sub-pixel SPX2, and the third sub-pixel SPX3 may emit light of a first color, light of a second color, and light of a third color, respectively. The light of the first color, the light of the second color, and the light of the third color may be, but are not limited to, a red light (e.g., light in a red wavelength band having a main peak wavelength of about 600 nm to 750 nm), a green light (e.g., light in a green wavelength band having a main peak wavelength of about 480 nm to 560 nm), and a blue light (e.g., light in a blue wavelength band having a main peak wavelength of about 370 nm to 460 nm), respectively. In an embodiment, the first sub-pixel SPX1, the second sub-pixel SPX2, and the third sub-pixel SPX3 of each of the pixels PX may be arranged along the first direction DR1. The number, type, arrangement structure, and/or light emitting wavelength of the sub-pixels SPX included in each of the pixels PX may be variously modified as needed or desired.

Each of the plurality of sub-pixels SPX may be connected to one of the write scan lines GWL, one of the initialization scan lines GIL, one of the control scan lines GCL, one of the bias scan lines GBL, one of the light emitting control lines EL1 and EL2, and one of the data lines DL. As used herein, the term “connection” may include a “physical connection” and/or an “electrical connection.”

Each of the plurality of sub-pixels SPX may be supplied with a data voltage of a data line DL according to a write scan signal of a write scan line GWL, and may emit light from a light emitting element according to the data voltage. The plurality of sub-pixels SPX included in each pixel PX may be connected to different data lines DL from each other. For example, the first sub-pixel SPX1, the second sub-pixel SPX2, and the third sub-pixel SPX3 may be connected to a first data line DLr, a second data line DLg, and a third data line DLb, respectively. Accordingly, a light-emitting luminance of each of the first sub-pixel SPX1, the second sub-pixel SPX2, and the third sub-pixel SPX3 may be individually controlled.

In an embodiment, each of the pixels PX is connected to two or more light emitting control lines EL, and light emitting periods (e.g., on-duty ratios) of at least two sub-pixels SPX among the plurality of sub-pixels SPX included in each pixel PX may be independently and/or individually controlled by different light emitting control signals supplied to the different light emitting control lines EL. For example, in each horizontal line (e.g., in each pixel row) of the display area DA, a first light emitting control line EL1 and a second light emitting control line EL2 may be arranged, which are connected to different sub-pixels SPX from each other among the sub-pixels SPX included in the pixels PX arranged in a corresponding horizontal line. For example, the first light emitting control line EL1 may be connected to the first sub-pixels SPX1 of the pixels PX arranged in the corresponding horizontal line, and the second light emitting control line EL2 may be connected to the second sub-pixels SPX2 and the third sub-pixels SPX3 included in the pixels PX of the corresponding horizontal line.

A light emitting driving portion EDC, a scan driving portion SDC, and a display driving circuit 250 may be arranged in the non-display area NDA.

The light emitting driving portion EDC receives a driving control signal ECS from the display driving circuit 250. The light emitting driving portion EDC may output light emitting control signals to the light emitting control lines EL in response to the driving control signal ECS.

In an embodiment, the light emitting driving portion EDC may include a first light emitting driver 611 and a second light emitting driver 612.

The first light emitting driver 611 may be connected to the first light emitting control line EL1. The second light emitting driver 612 may be connected to the second light emitting control line EL2.

The first sub-pixel SPX1 may emit light during a first light emitting period in response to a first light emitting control signal supplied through the first light emitting control line EL1. The first light emitting period may be a period during which a driving current may flow to the first sub-pixel SPX1 by the first light emitting control signal. The second sub-pixel SPX2 and the third sub-pixel SPX3 may emit light during a second light emitting period in response to a second light emitting control signal supplied through the second light emitting control line EL2. The second light emitting period may be a period during which a driving current may flow to the second sub-pixel SPX2 and the third sub-pixel SPX3 by the second light emitting control signal. The first light emitting period and the second light emitting period may be controlled independently or separately from each other, and may or may not temporally overlap with each other.

In an embodiment, the duration of the first light emitting period and the duration of the second light emitting period may be different from each other. For example, the duration of the first light emitting period may correspond to an on-duty ratio adjusted so that the first sub-pixel SPX1 emits light with a target luminance according to a driving current optimized for the light emitting efficiency of the first sub-pixel SPX1 (e.g., a driving current within a range in which the light emitting element of the first sub-pixel SPX1 exhibits an optimal consumption efficiency).

The duration of the second light emitting period may correspond to an on-duty ratio adjusted so that the second sub-pixel SPX2 and the third sub-pixel SPX3 emit light with a target luminance at a driving current optimized for the light emitting efficiency of the second sub-pixel SPX2 and the third sub-pixel SPX3 (e.g., a driving current within a range in which the light emitting elements of the second sub-pixel SPX2 and the third sub-pixel SPX3 exhibit an optimal consumption efficiency).

The scan driving portion SDC may be electrically connected to the pixels PX through the scan lines SL. For example, the scan driving portion SDC may be electrically connected to pixel circuits of the sub-pixels SPX included in each pixel PX through the write scan lines GWL, the initialization scan lines GIL, the control scan lines GCL, and the bias scan lines GBL.

The scan driving portion SDC may include a write scan signal driver 621, an initialization scan signal and control scan signal driver 622, and a bias scan signal driver 623. Each of the write scan signal driver 621, the initialization scan signal and control scan signal driver 622, and the bias scan signal driver 623 may receive a scan timing control signal SCS from a timing control circuit 251.

The write scan signal driver 621 may generate write scan signals according to the scan timing control signal SCS, and may sequentially output them to the write scan lines GWL.

The initialization scan signal and control scan signal driver 622 may generate initialization scan signals according to the scan timing control signal SCS, and may sequentially output them to the initialization scan lines GIL. Also, the initialization scan signal and control scan signal driver 622 may generate control scan signals according to the scan timing control signal SCS, and may sequentially output them to the control scan lines GCL.

The bias scan signal driver 623 may generate bias scan signals according to the scan timing control signal SCS, and may sequentially output them to the bias scan lines GBL.

The display driving circuit 250 may include the timing control circuit 251 and a data driving circuit 252.

The data driving circuit 252 may be electrically connected to the pixels PX through the data lines DL. For example, the data driving circuit 252 may be electrically connected to the pixel circuits of the sub-pixels SPX included in each pixel PX through the first data line DLr, the second data line DLg, and the third data line DLb.

The data driving circuit 252 may receive digital video data DATA and a data timing control signal DCS from the timing control circuit 251. The data driving circuit 252 converts the digital video data DATA into analog data voltages according to the data timing control signal DCS, and outputs the converted data to the data lines DL. In this case, the sub-pixels SPX may be selected by the write scan signal of the scan driving portion SDC, and the selected sub-pixels may receive the converted data via the data lines DL.

The timing control circuit 251 may receive the digital video data DATA and timing signals from the outside. The timing control circuit 251 may generate the scan timing control signal SCS and the data timing control signal DCS for controlling the display panel 100 according to the timing signals. The timing control circuit 251 may output the scan timing control signal SCS to the scan driving portion SDC. The timing control circuit 251 may output the digital video data DATA and the data timing control signal DCS to the data driving circuit 252.

The power supply circuit 500 may generate panel driving voltages according to a power voltage supplied from the outside. For example, the power supply circuit 500 may generate a first driving voltage VDD, a second driving voltage VSS, a third driving voltage VINT, a fourth driving voltage VAINT, and a fifth driving voltage VOBS, and may supply them to the display panel 100. The first driving voltage VDD, the second driving voltage VSS, the third driving voltage VINT, the fourth driving voltage VAINT, and the fifth driving voltage VOBS may be supplied to the sub-pixels SPX through respective power supply lines connected between the power supply circuit 500 and the sub-pixels SPX, and may be used to drive the sub-pixels SPX. Depending on the structure or an operation method of the sub-pixels SPX, the number and/or types of panel driving voltages output from the power supply circuit 500 may be variously modified.

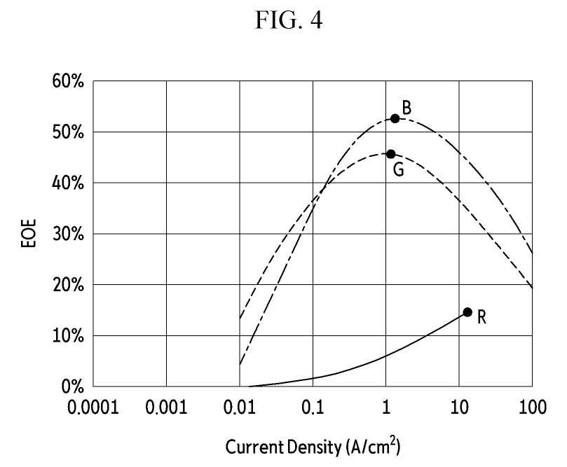

FIG. 4 is a graph illustrating an external quantum efficiency and current density sections of a sub-pixel according to an embodiment.

Semiconductor light emitting elements (hereinafter, micro LEDs) with a diameter or major axis length of several to several hundred micrometers tend to have lower external quantum efficiency EQE than those of light emitting elements of relatively larger sizes. The external quantum efficiency may generally refer to the number of photons generated relative to the injected carriers. In more detail, a carrier leakage may be severe at lower currents in early stages of operation, which may result in a decrease in the luminance of the element.

Referring to FIG. 4, the external quantum efficiency of the red-light emitting element R may be significantly lower than that of the blue-light emitting element B or that of the green-light emitting element G. Also, even in the optimal current density range that produces the optimal external quantum efficiency, the external quantum efficiency of the red-light emitting element R may be significantly lower than that of the blue-light emitting element B or that of the green-light emitting element G.

The on-duty ratio of a light emitting element that generally emits a red wavelength may be low, whereas the on-duty ratio of a light emitting element that emits a blue wavelength or a green wavelength may be relatively high. Nevertheless, when the on-duty ratios of the light emitting element that emits a red wavelength and the light emitting element that emits a blue wavelength or a green wavelength are identically reflected, the light emitting element that emits a red wavelength may use a low current density section, which increases a power consumption. Therefore, according to an embodiment, the light emitting control signals that control the light emitting element that emits a red wavelength and the light emitting control signals that control the light emitting element that emits a blue wavelength or a green wavelength may be separately operated by applying the first light emitting driver 611 and the second light emitting driver 612, thereby reducing a power consumption.

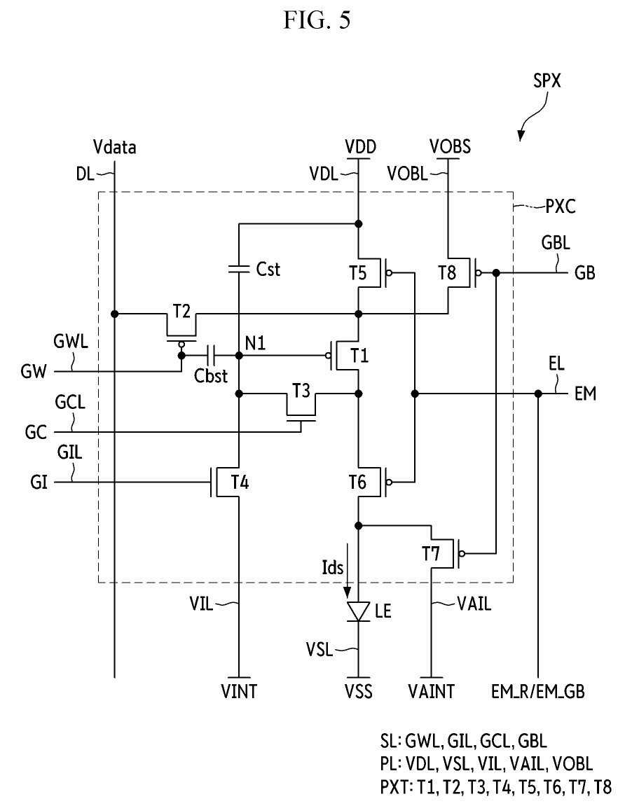

FIG. 5 is an equivalent circuit diagram illustrating a light emitting control signal and a sub-pixel according to an embodiment. For example, FIG. 5 may be an equivalent circuit diagram showing the sub-pixels SPX of FIGS. 2 and 3. In an embodiment, the circuit configurations of the plurality of sub-pixels SPX constituting each pixel PX may be the same or substantially the same as each other. For example, the equivalent circuit diagrams of the sub-pixels SPX may be the same or substantially the same as that of FIG. 5.

A first light emitting control signal EM_R may be input to the first sub-pixel SPX1, and a second light emitting control signal EM_GB may be input to the second sub-pixel SPX2 and the third sub-pixel SPX3. As such, the light emitting control signals of the first sub-pixel SPX1, the second sub-pixel SPX2, and the third sub-pixel SPX3 may be applied differently to use an optimal current density section for each sub-pixel SPX.

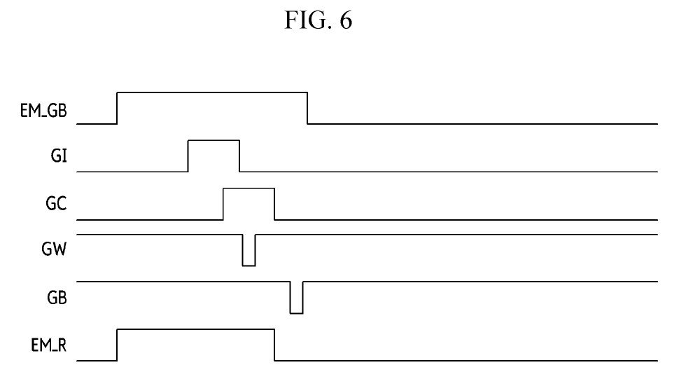

FIG. 6 is a waveform diagram illustrating driving signals of a sub-pixel according to an embodiment. For example, FIG. 6 illustrates a first light emitting control signal EM_R, a write scan signal GW, a control scan signal GC, an initialization scan signal GI, a bias scan signal GB, and a second light emitting control signal EM_GB supplied to the scan lines SL and the light emitting control lines EL of FIG. 5.

In addition to FIGS. 1 to 3, referring to FIGS. 5 and 6, each of the sub-pixels SPX may include a pixel circuit PXC, and a light emitting element LE electrically connected to the pixel circuit PXC.

The sub-pixel SPX may be connected to at least one scan driving portion through the scan lines SL and the light emitting control lines EL. For example, the first sub-pixel SPX1 may be connected to the light emitting driving portion EDC through the first light emitting control line EL1, and may be connected to the scan driving portion SDC through the write scan line GWL, the initialization scan line GIL, the control scan line GCL, and the bias scan line GBL. The second sub-pixel SPX1 and the third sub-pixel SPX2 may be connected to the light emitting driving portion EDC through the second light emitting control line EL2, and may be connected to the scan driving portion SDC through the write scan line GWL, the initialization scan line GIL, the control scan line GCL, and the bias scan line GBL.

The first light emitting driver 611 may output the first light emitting control signal EM_R to the first light emitting control line EL1.

The second light emitting driver 612 may output the second light emitting control signal EM_GB to the second light emitting control line EL2.

The scan driving portion SDC may output the write scan signal GW, the initialization scan signal GI, the control scan signal GC, and the bias scan signal GB to the write scan line GWL, the initialization scan line GIL, the control scan line GCL, and the bias scan line GBL, respectively.

When the sub-pixel SPX is the first sub-pixel SPX1, the sub-pixel SPX may be connected to the first light emitting control signal EM_R for the corresponding horizontal line, and may receive the first light emitting control signal EM_R from the first light emitting control line EL1. When the sub-pixel SPX is the second sub-pixel SPX2 or the third sub-pixel SPX3, the sub-pixel SPX may be connected to the second light emitting control line EL2 for the corresponding horizontal line, and may receive the second light emitting control signal EM_GB from the second light emitting control line EL2.

The sub-pixel SPX may be connected to the data driving circuit 252 through the data line DL. The data driving circuit 252 may output the data voltage Vdata corresponding to the image data of each frame to the data line DL.

When the sub-pixel SPX is the first sub-pixel SPX1, the sub-pixel SPX may be connected to the first data line DLr arranged in the corresponding pixel column. When the sub-pixel SPX is the second sub-pixel SPX2, the sub-pixel SPX may be connected to the second data line DLg arranged in the corresponding pixel column. When the sub-pixel SPX is the third sub-pixel SPX3, the sub-pixel SPX may be connected to the third data line DLb arranged in the corresponding pixel column.

The sub-pixel SPX may be connected to the power supply circuit 500 through the power supply lines PL. For example, the sub-pixel SPX may be connected to the power supply circuit 500 through the first power supply line VDL, the second power supply line VSL, the third power supply line VIL, the fourth power supply line VAIL, and the fifth power supply line VOBL. The power supply circuit 500 may supply the first driving voltage VDD, the second driving voltage VSS, the third driving voltage VINT, the fourth driving voltage VAINT, and the fifth driving voltage VOBS to the first power supply line VDL, the second power supply line VSL, the third power supply line VIL, the fourth power supply line VAIL, and the fifth power supply line VOBL, respectively. In an embodiment, the first power supply line VDL, the second power supply line VSL, the third power supply line VIL, the fourth power supply line VAIL, and the fifth power supply line VOBL may be applied with a high-potential pixel voltage (e.g., an anode voltage), a low-potential pixel voltage (e.g., a cathode voltage or a common voltage), a first initialization voltage (e.g., a gate initialization voltage), a second initialization voltage (e.g., an anode initialization voltage), and a bias voltage, respectively.

The pixel circuit PXC may control a driving current Ids supplied to the light emitting element LE in response to the driving signals supplied to the sub-pixel SPX (e.g., a write scan signal GW, an initialization scan signal GI, a control scan signal GC, a bias scan signal GB, a first light emitting control signal EM_R, a second light emitting control signal EM_GB, and a data voltage Vdata). The light emitting timing and the luminance of the light emitting element LE may be controlled by the pixel circuit PXC.

The pixel circuit PXC may include pixel transistors PXT and a storage capacitor Cst. In an embodiment, the pixel circuit PXC may further include a boosting capacitor Cbst.

In an embodiment, the pixel transistors PXT may include first to eighth transistors T1 to T8. The first transistor T1 may be a driving transistor of the sub-pixel SPX. The second to eighth transistors T2 to T8 may be switching transistors of the sub-pixel SPX.

In an embodiment, the sub-pixel SPX may include heterogeneous pixel transistors PXT. For example, the first, second, fifth, sixth, seventh, and eighth transistors T1, T2, T5, T6, T7, and T8 may be P-type transistors (e.g., P-type polycrystalline silicon transistors, each including active layers formed of polycrystalline silicon), and the third and fourth transistors T3 and T4 may be N-type transistors (e.g., N-type oxide transistors, each including active layers formed of oxide semiconductors). In an embodiment, the active layers of the P-type transistors (e.g., the active layers formed of polycrystalline silicon) and the active layers of the N-type transistors (e.g., the active layers formed of oxide semiconductors) may be arranged in different layers from each other within the display panel 100 (e.g., a backplane layer of the display panel 100).

The first transistor T1 may be connected between the fifth transistor T5 and the sixth transistor T6. The first transistor T1 may be connected to the first power supply line VDL through the fifth transistor T5, and to the light emitting element LE through the sixth transistor T6. The gate electrode of the first transistor T1 may be connected to a first node N1. The first transistor T1 may control the driving current Ids flowing to the sub-pixel SPX according to the voltage of the first node N1 (e.g., a voltage corresponding to the data voltage Vdata) applied to the gate electrode thereof.

The second transistor T2 may be connected between the data line DL and the first electrode of the first transistor T1 (e.g., the source electrode of the first transistor T1 connected to the fifth transistor T5). The gate electrode of the second transistor T2 may be connected to the write scan line GWL. The second transistor T2 may be turned on by the write scan signal GW of the gate-on voltage (e.g., a low-level voltage at which the second transistor T2 may be turned on) supplied from the write scan line GWL. When the second transistor T2 is turned on, the data voltage Vdata supplied from the data line DL may be transmitted to the first electrode (e.g., the source electrode) of the first transistor T1.

The third transistor T3 may be connected between the second electrode of the first transistor T1 (e.g., the drain electrode of the first transistor T1 connected to the sixth transistor T6) and the first node N1. The gate electrode of the third transistor T3 may be connected to the control scan line GCL. The third transistor T3 may be turned on by a control scan signal GC of a gate-on voltage supplied from a control scan line GCL (e.g., a high-level voltage at which the third transistor T3 may be turned on) to connect the gate electrode and the second electrode of the first transistor T1 to each other. When the third transistor T3 is turned on, the first transistor T1 may be driven as a diode, and a voltage corresponding to the data voltage Vdata may be applied to the first node N1.

The fourth transistor T4 may be connected between the first node N1 and the third power supply line VIL. The gate electrode of the fourth transistor T4 may be connected to the initialization scan line GIL. The fourth transistor T4 may be turned on by an initialization scan signal GI of a gate-on voltage (e.g., a high-level voltage at which the fourth transistor T4 may be turned on) supplied from an initialization scan line GIL to connect the first node N1 to a third power supply line VIL. When the fourth transistor T4 is turned on, the voltage of the first node N1 may be initialized to a third driving voltage VINT of the third power supply line VIL.

The fifth transistor T5 may be connected between the first power supply line VDL and the first electrode of the first transistor T1. The gate electrode of the fifth transistor T5 may be connected to the first light emitting control line EL1 or the second light emitting control line EL2 of FIG. 3. The fifth transistor T5 may be turned on by the light emitting control signal EM_R or EM_GB of the gate-on voltage (e.g., a low-level voltage at which the fifth transistor T5 may be turned on) supplied from the first light emitting control line EL1 or the second light emitting control line EL2, thereby connecting the first electrode of the first transistor T1 to the first power supply line VDL. When the fifth transistor T5 is turned on, the first power supply line VDL may be connected to the first electrode of the first transistor T1.

The sixth transistor T6 may be connected between the second electrode of the first transistor T1 and the light emitting element LE. The gate electrode of the sixth transistor T6 may be connected to the light emitting control line EL1 or EL2. The sixth transistor T6 may be turned on by the light emitting control signal EM of a gate-on voltage (e.g., a low-level voltage at which the sixth transistor T6 may be turned on) supplied from the light emitting control line EL to connect the second electrode of the first transistor T1 to the light emitting element LE.

The seventh transistor T7 may be connected between the first electrode of the light emitting element LE (e.g., an anode electrode connected to the sixth transistor T6) and the fourth power supply line VAIL. The gate electrode of the fourth transistor T4 may be connected to a bias scan line GBL. The seventh transistor T7 may be turned on by a bias scan signal GB of a gate-on voltage (e.g., a low-level voltage at which the seventh transistor T7 may be turned on) supplied from the bias scan line GBL to connect the first electrode of the light emitting element LE to the fourth power supply line VAIL. When the seventh transistor T7 is turned on, the voltage of the first electrode of the light emitting element LE may be initialized to the fourth driving voltage VAINT of the fourth power supply line VAIL.

The eighth transistor T8 may be connected between the fifth power supply line VOBL and the first electrode of the first transistor T1. The gate electrode of the eighth transistor T8 may be connected to the bias scan line GBL. The eighth transistor T8 may be turned on by the bias scan signal GB of the gate-on voltage supplied from the bias scan line GBL to connect the first electrode of the first transistor T1 to the fifth power supply line VOBL. When the eighth transistor T8 is turned on, the voltage of the first electrode of the first transistor T1 may be initialized to the fifth driving voltage VOBS of the fifth power supply line VOBL. In an embodiment, the fifth driving voltage VOBS may be a bias voltage having a voltage level suitable for compensating a hysteresis characteristic of the first transistor T1.

The storage capacitor Cst may be connected between the first node N1 and the first power supply line VDL. The storage capacitor Cst may be charged with a voltage corresponding to the data voltage Vdata applied to the first node N1.

The boosting capacitor Cbst may be connected between the first node N1 and the write scan line GWL. The voltage of the first node N1 may be stabilized by a coupling action of the boosting capacitor Cbst, thereby stabilizing the operation of the first transistor T1. The boosting capacitor Cbst may be formed by a parasitic capacitance formed between the first node N1 and the write scan line GWL, or may be separately formed.

The sub-pixel SPX may emit light for a portion of a period corresponding to an on-duty ratio during each frame period, and may not emit light for a remaining period. The emission period and the non-emission period of the sub-pixel SPX may be controlled by the light emitting control signal EM. For example, the emission period and the non-emission period of the first sub-pixel SPX1 may be controlled by the first light emitting control signal EM_R. The emission periods and the non-emission periods of the second sub-pixel SPX2 and the third sub-pixel SPX3 may be controlled by the second light emitting control signal EM_GB.

The period during which the fifth transistor T5 and the sixth transistor T6 are turned off (e.g., a period during which a high-level light emitting control signal EM_R or EM_GB is supplied to the sub-pixel SPX) may be a non-emission period of the sub-pixel SPX. For example, the period during which a high-level first light emitting control signal EM_R is supplied to the first sub-pixel SPX1 may be a non-emission period of the first sub-pixel SPX1. The period during which a high-level second light emitting control signal EM_GB is supplied to the second sub-pixel SPX2 or the third sub-pixel SPX3 may be a non-emission period of the second sub-pixel SPX2 or the third sub-pixel SPX3. The non-emission period of the sub-pixel SPX may include an initialization period for initializing the voltage of a node (e.g., the first node N1 and/or the like) of the sub-pixel (SPX), and a data writing and storage period to charge a voltage corresponding to the data voltage Vdata to the storage capacitor Cst. In an embodiment, an initialization scan signal GI of a gate-on voltage, a control scan signal GC, a writing scan signal GW, and a bias scan signal GB may be supplied during the non-emission period of the sub-pixel SPX. In an embodiment, the initialization scan signal GI of a gate-on voltage, a control scan signal GC, and a bias scan signal GB may be sequentially supplied during the non-emission period of the sub-pixel SPX. The periods during which the initialization scan signal GI of the gate-on voltage and the control scan signal GC are supplied may overlap with each other, but the present disclosure is not limited thereto. The writing scan signal GW of the gate-on voltage may be supplied during the period in which the control scan signal GC of the gate-on voltage is supplied.

The period during which the fifth transistor T5 and the sixth transistor T6 are turned on (e.g., the period during which the low-level light light emitting control signal EM_R or EM_GB is supplied to the sub-pixel SPX) may be the light emission period of the sub-pixel SPX. For example, the period during which the low-level first light light emitting control signal EM_R is supplied to the first sub-pixel SPX1 may be the light emission period of the first sub-pixel SPX1. The period during which the low-level second light light emitting control signal EM_GB is supplied to the second sub-pixel SPX2 or the third sub-pixel SPX3 may be the light emission period of the second sub-pixel SPX2 or the third sub-pixel SPX3. During the light emission period of the sub-pixel SPX, the first transistor T1 may supply the driving current Ids corresponding to the voltage of the first node N1 to the light emitting element LE.

The light emitting element LE may be connected between the pixel circuit PXC and the second power line VSL. For example, the first electrode (e.g., the anode electrode or the pixel electrode) of the light emitting element LE may be connected to a node between the sixth transistor T6 and the seventh transistor T7, and the second electrode (e.g., the cathode electrode or the common electrode) of the light emitting element LE may be connected to the second power supply line VSL. The light emitting element LE may emit light in response to the driving current Ids supplied from the pixel circuit PXC.

In an embodiment, the sub-pixel SPX may include a single light emitting element LE, but the present disclosure is not limited thereto. For example, the sub-pixel SPX may include at least two light emitting elements LE. The at least two light emitting elements LE may be connected to each other in a series, parallel, or series-parallel structure between the pixel circuit PXC and the second power supply line VSL.

In an embodiment, the light emitting element LE may be a micro light emitting diode including an inorganic compound, such as a nitride-based or phosphide-based semiconductor material, but the present disclosure is not limited thereto. For example, the light emitting element LE may be an organic light emitting element, a quantum dot light emitting element, or another kinds of light emitting element. Also, the size or the shape of the light emitting element LE may be variously modified as needed or desired.

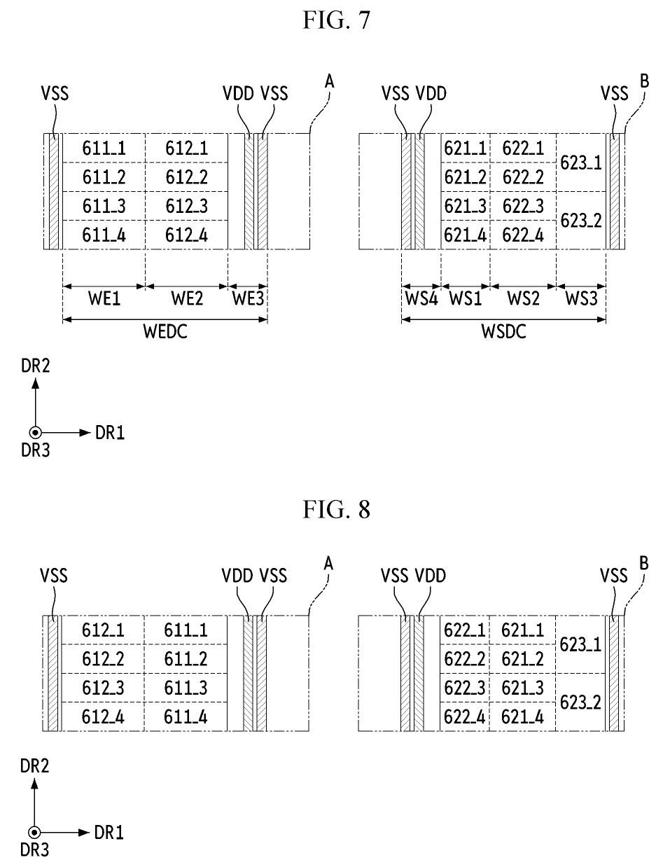

FIG. 7 is an enlarged view of the areas A and B of FIG. 2 according to an embodiment.

In addition to FIGS. 1 to 3, referring to FIG. 7, the light emitting driving portion EDC may be arranged in the non-display area NDA on a first side (e.g., the left side), and may include a plurality of first light emitting drivers (611_1, 611_2, 611_3, 611_4...) and a plurality of second light emitting drivers (612_1, 612_2, 612_3, 612_4...). The plurality of first light emitting drivers (611_1, 611_2, 611_3, 611_4...) may be arranged farther from the display area DA than the plurality of second light emitting drivers (612_1, 612_2, 612_3, 612_4...). In other words, the plurality of first light emitting drivers (611_1, 611_2, 611_3, 611_4…) may be arranged further outward than the plurality of second light emitting drivers (612_1, 612_2, 612_3, 612_4…).

The scan driving portion SDC may be arranged in the non-display area NDA on a second side (e.g., the right side) opposite to the first side, and may include a plurality of write scan signal drivers (621_1, 621_2, 621_3, 621_4…), a plurality of initialization scan signal and control scan signal drivers (622_1, 622_2, 622_3, 622_4…), and a plurality of bias scan signal drivers (623_1, 623_2, 623_3, 623_4…). The plurality of write scan signal drivers (621_1, 621_2, 621_3, 621_4…), the plurality of initialization scan signal and control scan signal drivers (622_1, 622_2, 622_3, 622_4…), and the plurality of bias scan signal drivers (623_1, 623_2, 623_3, 623_4…) may be sequentially arranged away from the display area DA. Accordingly, the plurality of bias scan signal drivers (623_1, 623_2, 623_3, 623_4…) may be arranged at the outermost side, and the plurality of write scan signal drivers (621_1, 621_2, 621_3, 621_4…) may be arranged at the innermost side.

A width WEDC in the first direction DR1 of the area where the light emitting driving portion EDC is arranged may be about 600㎛ to 610 ㎛, and a width WSDC in the first direction DR1 of the area where the scan driving portion SDC is arranged may be about 600 ㎛ to 610 ㎛, which may be the same or substantially the same (or similar to) each other. The light emitting driving portion EDC and the scan driving portion SDC may be arranged symmetrically with each other with the display area DA as the center.

The number of the plurality of first light emitting drivers (611_1, 611_2, 611_3, 611_4…) may be the same as the number of the plurality of second light emitting drivers (612_1, 612_2, 612_3, 612_4…). The sizes of the plurality of first light emitting drivers (611_1, 611_2, 611_3, 611_4…) may be the same as the sizes of the plurality of second light emitting drivers (612_1, 612_2, 612_3, 612_4…). The areas of the plurality of first light emitting drivers (611_1, 611_2, 611_3, 611_4…) may be the same as the areas of the plurality of second light emitting drivers (612_1, 612_2, 612_3, 612_4…). For example, the width WE1 of each of the plurality of first light emitting drivers (611_1, 611_2, 611_3, 611_4...) in the first direction DR1 may be about 215 ㎛ to 225 ㎛, and the width WE2 of each of the plurality of second light emitting drivers (612_1, 612_2, 612_3, 612_4...) in the first direction DR1 may be about 215 ㎛ to 225 ㎛. In an embodiment, the width WE1 of each of the first light emitting drivers (611_1, 611_2, 611_3, 611_4...) in the first direction DR1 and the width WE2 of each of the plurality of second light emitting drivers (612_1, 612_2, 612_3, 612_4...) in the first direction DR1 may be about 220 μm, and the width WE3 of a power supply line arrangement area in the first direction DR1 may be about 160 μm. Accordingly, the width WEDC of the light emitting driving portion EDC in the first direction DR1 may be about 600 μm.

The area of the write scan signal driver 621 of the scan driving portion SDC, the area of the initialization scan signal and a plurality of control scan signal drivers 622, and the bias scan signal driver 623 may be increased in sequence.

The number of the plurality of write scan signal drivers (621_1, 621_2, 621_3, 621_4…) and the number of the plurality of initialization scan signal and control scan signal drivers (622_1, 622_2, 622_3, 622_4…) may be the same as each other. A width WS1 of each of the plurality of write scan signal drivers (621_1, 621_2, 621_3, 621_4…) in the first direction DR1 may be about 145 µm to 155 µm, a width WS2 of each of the plurality of initialization scan signal and control scan signal drivers (622_1, 622_2, 622_3, 622_4…) in the first direction DR1 may be about 195 µm to 205 µm, and a width WS3 of each of the plurality of bias scan signal drivers (623_1, 623_2, 623_3, 623_4…) in the first direction DR1 may be about 95 µm to 105 µm. The number of the plurality of bias scan signal drivers (623_1, 623_2, 623_3, 623_4…) may be less than the number of the plurality of write scan signal drivers (621_1, 621_2, 621_3, 621_4…) and the number of the plurality of initialization scan signal and control scan signal drivers (622_1, 622_2, 622_3, 622_4…). The width WS1 in the first direction DR1 of the write scan signal drivers (621_1, 621_2, 621_3, 621_4...) may be about 150 μm, the width WS2 in the first direction DR1 of the plurality of initialization scan signal and control scan signal drivers (622_1, 622_2, 622_3, 622_4...) may be about 200 μm, and the width WS3 of each of the plurality of bias scan signal drivers (623_1, 623_2, 623_3, 623_4...) may be about 100 μm. A width WS4 in the first direction DR1 of the power supply line arrangement area may be about 155 μm. Therefore, the width WSDC in the first direction DR1 of the scan driving portion SDC may be about 605 μm.

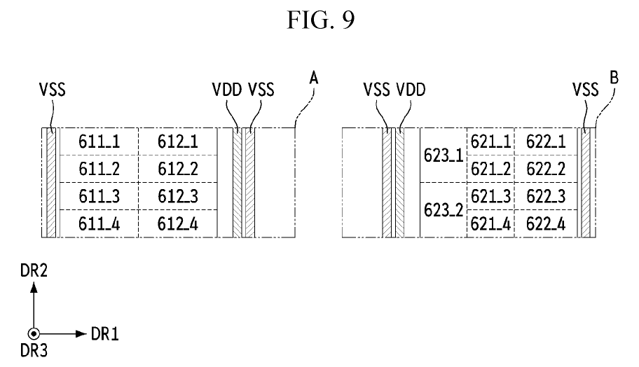

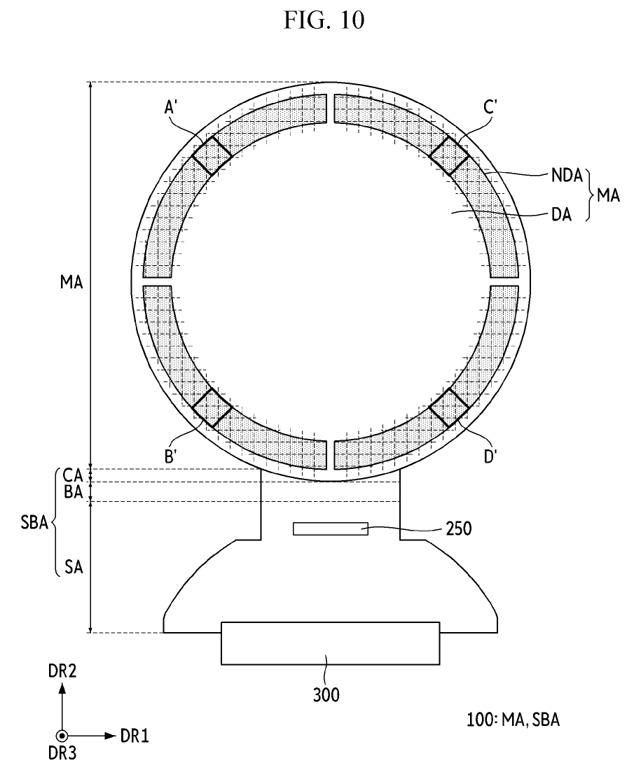

FIG. 8 is an enlarged view of the areas A and B of FIG. 2 according to an embodiment. FIG. 9 is an enlarged view of the areas A and B of FIG. 2 according to an embodiment.

The embodiments illustrated in FIGS. 8 and 9 may be different from the embodiment illustrated in FIG. 7, in that the arrangement of the drivers in the light emitting driving portion EDC and the arrangement of the drivers in the scan driving portion SDC may be different. Hereinafter with reference to FIGS. 8 and 9, redundant description of the same or substantially the same elements and configurations as those described above with reference to FIG. 7 may not be repeated, and the differences may be mainly described in more detail.

Referring to FIG. 8, in the light emitting driving portion EDC, a plurality of second light emitting drivers 612 may be arranged further outside than a plurality of first light emitting drivers 611.

In the scan driving portion SDC, a plurality of initialization scan signal and control scan signal drivers (622_1, 622_2, 622_3, 622_4…) may be arranged further inside than a plurality of write scan signal drivers (621_1, 621_2, 621_3, 621_4…).

Referring to FIG. 9, a plurality of bias scan signal drivers (623_1, 623_2, 623_3, 623_4…), a plurality of write scan signal drivers (621_1, 621_2, 621_3, 621_4…), and a plurality of initialization scan signal and control scan signal drivers (622_1, 622_2, 622_3, 622_4…) may be sequentially arranged from the inner side to the outer side.

Referring to FIGS. 7 to 9, the drivers may be symmetrically arranged with each other in the non-display area NDA on the left and right sides of the display area DA. Therefore, the non-display area NDA may have a symmetrical shape with the first side and the second side centered on the display area DA.

The second light emitting driver 612 is arranged on the first side of the non-display area NDA of the first light emitting driver 611, and the second light emitting driver 612 and the first light emitting driver 611 may have the same size as each other while there may be no restriction on their positions within the light emitting driving portion EDC. The first light emitting driver 611 may be arranged close to the display area DA, and the second light emitting driver 612 may be arranged close to the display area DA. The plurality of bias scan signal drivers (623_1, 623_2, 623_3, 623_4…), the plurality of write scan signal drivers (621_1, 621_2, 621_3, 621_4…), and the plurality of initialization scan signal and control scan signal drivers (622_1, 622_2, 622_3, 622_4…) may be arranged on the second side of the non-display area NDA, and there may be no positional constraints between each driver. However, in terms of a wiring resistance, it may be desirable to place the smallest driver among the plurality of bias scan signal drivers (623_1, 623_2, 623_3, 623_4…), the plurality of write scan signal drivers (621_1, 621_2, 621_3, 621_4…), and the plurality of initialization scan signal and control scan signal drivers (622_1, 622_2, 622_3, 622_4…) closer to the display area DA. Because the connection wiring connecting to the driver located outside the display area DA may bypass the driver located relatively inside.

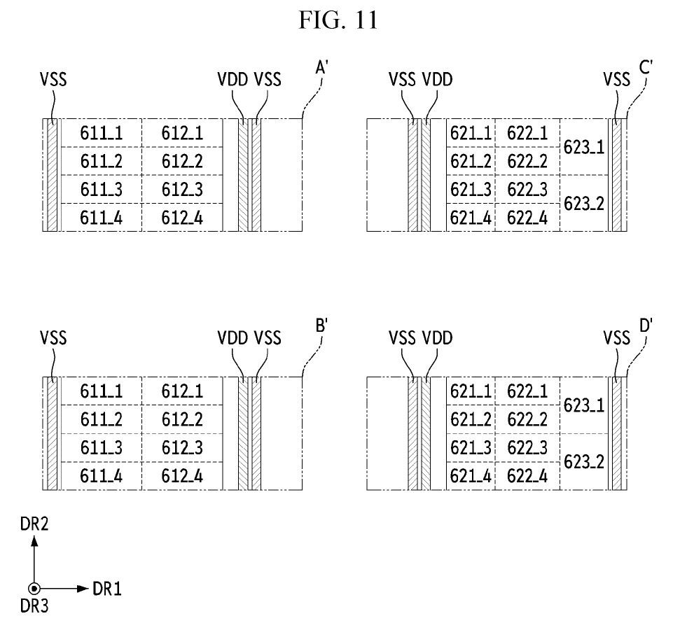

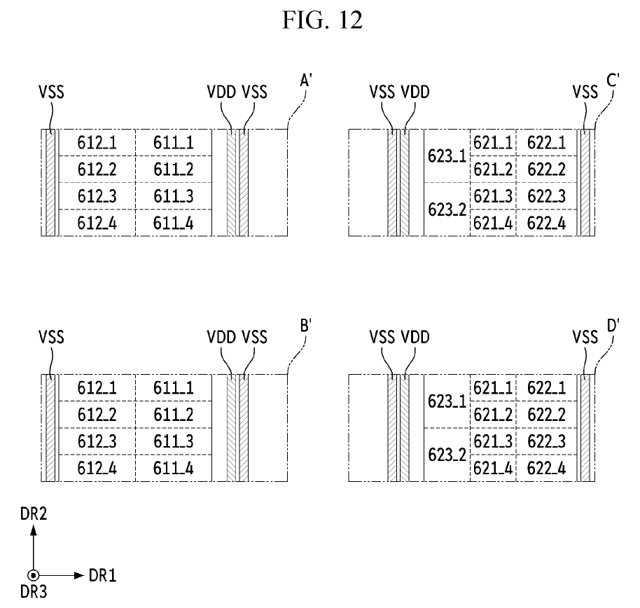

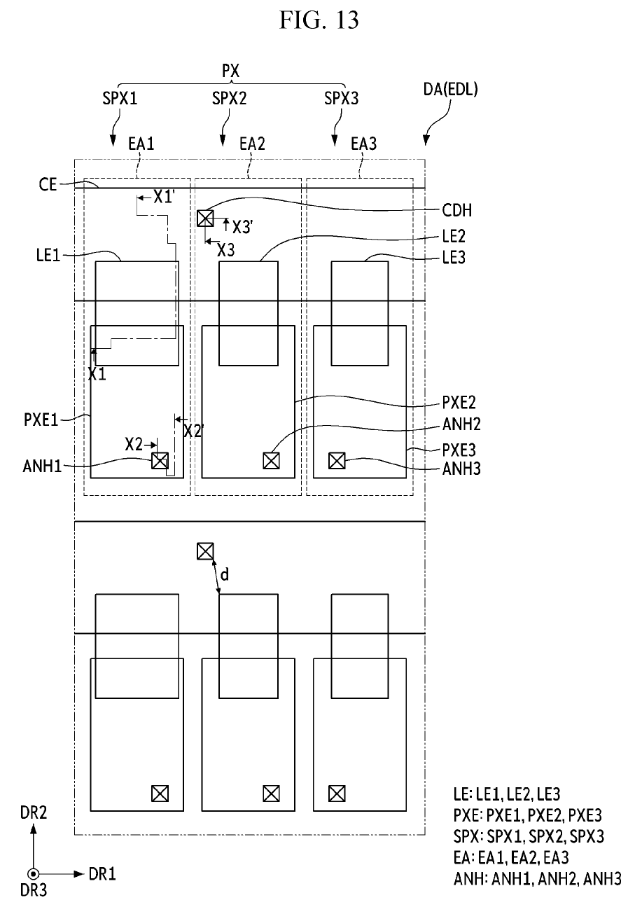

FIG. 10 is a plan view illustrating a display panel according to an embodiment. FIG. 11 is an enlarged view of the areas A’, B’, C’, and D’ of FIG. 10 according to an embodiment. FIG. 12 is an enlarged view of the areas A’, B’, C’, and D’ of FIG. 10 according to an embodiment.

Referring to FIG. 10, the display panel 100 may be different from the display panel 100 of FIG. 2 in that it is circular. Hereinafter with reference to FIG. 10, redundant description of the same or substantially the same elements and configurations as those described above with reference to FIG. 2 may not be repeated, and the difference may be described in more detail.

Referring to FIG. 10, the display panel 100 may include a display area DA and a non-display area NDA. The display area DA may include a circular shape in a plane (e.g., in a plan view). The non-display area NDA may be arranged around the display area DA. The non-display area NDA may be a bezel area. The non-display area NDA may surround (e.g., around a periphery of) the display area DA.

Referring to FIG. 10 and FIG. 11, the non-display area NDA may include the C’ area in a first quadrant, the A’ area in a second quadrant, the B’ area in a third quadrant, and the D’ area in a fourth quadrant. The light emitting driving portion EDC may be arranged in the A’ area of the second quadrant and the B’ area of the third quadrant of the non-display area NDA, and the scan driving portion SDC may be arranged in the C’ area of the first quadrant and the D’ area of the fourth quadrant.

A driver placement in the A’ area of the second quadrant and the B’ area of the third quadrant of the non-display area NDA may be the same or substantially the same as each other. A driver placement in the C’ area of the first quadrant and the D’ area of the fourth quadrant of the non-display area NDA may be the same or substantially the same as each other. Therefore, for convenience of illustration, the A’ area of the second quadrant and the C’ area of the first quadrant will be described in more detail hereinafter.

The light emitting driving portion EDC of the A’ area of the second quadrant may include a plurality of first light emitting drivers (611_1, 611_2, 611_3, 611_4…) and a plurality of second light emitting drivers (612_1, 612_2, 612_3, 612_4…).

The number of the plurality of first light emitting drivers (611_1, 611_2, 611_3, 611_4…) may be the same as the number of the plurality of second light emitting drivers (612_1, 612_2, 612_3, 612_4…). The sizes of the plurality of first light emitting drivers (611_1, 611_2, 611_3, 611_4…) may be the same as the sizes of the plurality of second light emitting drivers (612_1, 612_2, 612_3, 612_4…).

The scan driving portion SDC of the C’ area of the first quadrant may include a plurality of write scan signal drivers (621_1, 621_2, 621_3, 621_4…), a plurality of initialization scan signal and control scan signal drivers (622_1, 622_2, 622_3, 622_4…), and a plurality of bias scan signal drivers (623_1, 623_2, 623_3, 623_4…). The plurality of first light emitting drivers (611_1, 611_2, 611_3, 611_4…) may be arranged further away from the display area DA than the plurality of second light emitting drivers (612_1, 612_2, 612_3, 612_4…). In other words, the plurality of first light emitting drivers (611_1, 611_2, 611_3, 611_4…) may be arranged further outside than the plurality of second light emitting drivers (612_1, 612_2, 612_3, 612_4…).

The plurality of write scan signal drivers (621_1, 621_2, 621_3, 621_4…), the plurality of initialization scan signal and control scan signal drivers (622_1, 622_2, 622_3, 622_4…), and the plurality of bias scan signal drivers (623_1, 623_2, 623_3, 623_4…) may be sequentially arranged away from the display area DA. Accordingly, the plurality of bias scan signal drivers (623_1, 623_2, 623_3, 623_4…) may be arranged at the outermost side, and the plurality of write scan signal drivers (621_1, 621_2, 621_3, 621_4…) may be arranged at the innermost side.

The number of the plurality of write scan signal drivers (621_1, 621_2, 621_3, 621_4…) and the number of the plurality of initialization scan signal and control scan signal drivers (622_1, 622_2, 622_3, 622_4…) may be the same as each other.

Referring to FIG. 10 and FIG. 12, in the light emitting driving portion EDC, the plurality of second light emitting drivers 612 may be arranged further outside than the plurality of first light emitting drivers 611.

The plurality of bias scan signal drivers (623_1, 623_2, 623_3, 623_4…), the plurality of write scan signal drivers (621_1, 621_2, 621_3, 621_4…), and the plurality of initialization scan signal and control scan signal drivers (622_1, 622_2, 622_3, 622_4…) may be sequentially arranged from the inside to the outside.

The size of each driver shown in FIGS. 11 and 12 may be the same as the size of the corresponding driver described above with reference to FIG. 7, and thus, redundant description thereof may not be repeated hereinafter.

Referring to FIGS. 10 to 12, in the display panel 100 having the circular display area DA, the first light emitting driver 611 and the second light emitting driver 612 may be arranged on a first side (e.g., the left side) of the non-display area NDA, and the write scan signal drivers 621, the initialization scan signal and the plurality of control scan signal drivers 622, and the bias scan signal drivers 623 may be symmetrically arranged on a second side (e.g., the right side) of the non-display area NDA.

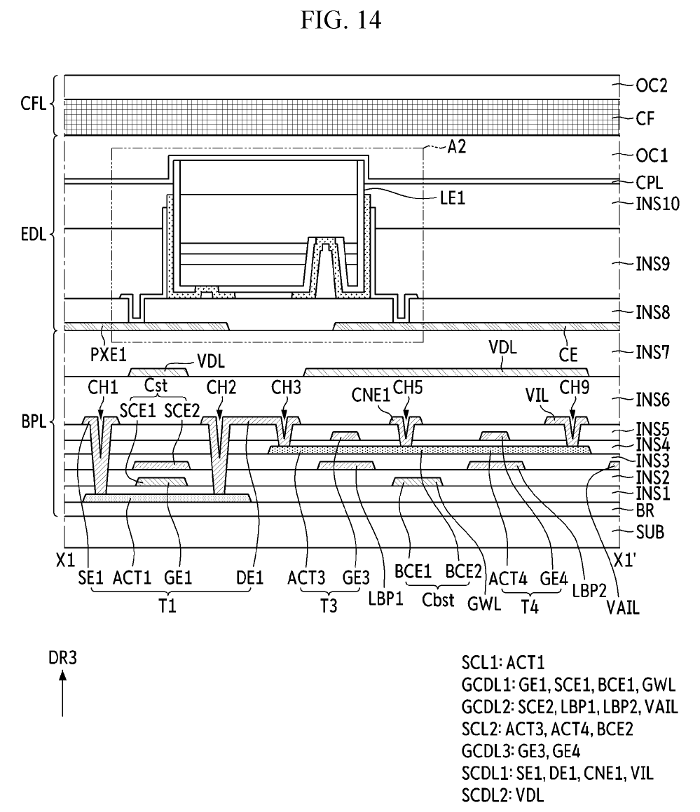

FIG. 13 is a layout diagram illustrating a light emitting element layer of a display panel according to an embodiment. For example, FIG. 13 illustrates light emitting elements LE, pixel electrodes PXE, and common electrodes CE included in sub-pixels SPX of each pixel PX in a portion of a display area DA in which two adjacent pixels PX are arranged in a second direction DR2.

In addition to FIGS. 3 to 12, referring to FIG. 13, each of the sub-pixels SPX may include a pixel electrode PXE and a light emitting element LE arranged in a light emitting area EA. In an embodiment, when the light emitting element LE is a micro LED of a flip-chip kind or a lateral kind, each of the sub-pixels SPX may further include a common electrode CE arranged on one surface (e.g., a bottom surface or a top surface) of the light emitting element LE together with the pixel electrode PXE.

In FIG. 13, the sizes of the light emitting areas EA of the sub-pixels SPX are illustrated as being the same as each other, but the present disclosure is not limited thereto. For example, the sizes of the light emitting areas EA of the sub-pixels SPX may be differentiated or optimized according to the light-emitting characteristics or the target luminance of each light emitting element LE and/or sub-pixel SPX.

In addition, in FIG. 13, the pixel electrodes PXE are illustrated as being located inside (e.g., only inside) the corresponding light emitting area EA, but the present disclosure is not limited thereto. For example, at least a portion of one pixel electrode PXE may be arranged in a non-emission area around the light emitting area EA. For example, the sizes, the shapes, and/or the arrangement directions of the pixel electrodes PXE may be variously modified as needed or desired.

In an embodiment, the sub-pixels SPX of each pixel PX may be arranged along a first direction DR1. Also, the sub-pixels SPX of each pixel PX may share one common electrode CE. For example, the common electrode CE extends in the first direction DR1 in each horizontal line of the display area DA, and the sub-pixels SPX of the pixels PX arranged in the corresponding horizontal line may share one common electrode CE.

The first sub-pixel SPX1 may include a first pixel electrode PXE1, a first light emitting element LE1, and a common electrode CE (e.g., a portion of the common electrode CE) arranged in a first light emitting area EA1. The first light emitting area EA1 may refer to the light emitting area EA of the first sub-pixel SPX1. The first light emitting element LE1 may refer to the light emitting element LE of the first sub-pixel SPX1.

The second sub-pixel SPX2 may include a second pixel electrode PXE2, a second light emitting element LE2, and a common electrode CE arranged in a second light emitting area EA2. The second light emitting area EA2 may refer to the light emitting area EA of the second sub-pixel SPX2. The second light emitting element LE2 may refer to the light emitting element LE of the second sub-pixel SPX2.

The third sub-pixel SPX3 may include a third pixel electrode PXE3, a third light-emitting element LE3, and a common electrode CE arranged in the third light emitting area EA3. The third light-emitting area EA3 may refer to the light emitting area EA of the third sub-pixel SPX3. The third light emitting element LE3 may refer to the light emitting element LE of the third sub-pixel SPX3.

In each pixel PX, the first pixel electrode PXE1, the second pixel electrode PXE2, and the third pixel electrode PXE3 may be arranged along the first direction DR1. The first pixel electrode PXE1, the second pixel electrode PXE2, and the third pixel electrode PXE3 may be spaced apart from the common electrode CE in the second direction DR2.

The pixel electrodes PXE may be electrically connected to respective pixel circuits PXC through respective anode contact holes ANH. For example, the first pixel electrode PXE1 may be electrically connected to the first pixel circuit PXC1 through a first anode contact hole ANH1. The second pixel electrode PXE2 may be electrically connected to the second pixel circuit PXC2 through a second anode contact hole ANH2. The third pixel electrode PXE3 may be electrically connected to the third pixel circuit PXC3 through a third anode contact hole ANH3.

The light emitting elements LE may be arranged between each of the pixel electrodes PXE and the common electrode CE. For example, the first light emitting element LE1 may be arranged on the first pixel electrode PXE1 and the common electrode CE. A portion of the first light emitting element LE1 may overlap with the first pixel electrode PXE1, and another portion of the first light emitting element LE1 may overlap with the common electrode CE. The first light emitting element LE1 may be electrically connected between the first pixel electrode PXE1 and the common electrode CE. The second light emitting element LE2 may be arranged on the second pixel electrode PXE2 and the common electrode CE. A portion of the second light emitting element LE2 may overlap with the second pixel electrode PXE2, and another portion of the second light emitting element LE2 may overlap with the common electrode CE. The second light emitting element LE2 may be electrically connected between the second pixel electrode PXE2 and the common electrode CE. The third light emitting element LE3 is arranged on the third pixel electrode PXE3 and the common electrode CE. A portion of the third light emitting element LE3 may overlap with the third pixel electrode PXE3, and another portion of the third light emitting element LE3 may overlap with the common electrode CE. The third light emitting element LE3 may be electrically connected between the third pixel electrode PXE3 and the common electrode CE.

Each of the light emitting elements LE may emit light of a desired color (e.g., a red light, a green light, a blue light, or a white light). In an embodiment, the first light emitting element LE1, the second light emitting element LE2, and the third light emitting element LE3 may emit light of different colors from each other. For example, the first light emitting element LE1, the second light emitting element LE2, and the third light emitting element LE3 may emit light of a first color (e.g., a red light), light of a second color (e.g., a green light), and light of a third color (e.g., a blue light), respectively.

In an embodiment, the light emitting elements LE of at least two sub-pixels SPX may have different sizes from each other. For example, the size of the first light emitting element LE1 may be larger than the sizes of each of the second light emitting element LE2 and the third light emitting element LE3.

In an embodiment, the light emitting elements LE may have differentiated or optimized sizes depending on the light emitting efficiency of the light emitting elements LE and/or the like. For example, at least two of the light emitting elements LE among the first light emitting element LE1, the second light emitting element LE2, and the third light emitting element LE3 may have different sizes from each other depending on the light emitting efficiency of each of the first light emitting element LE1, the second light emitting element LE2, and the third light emitting element LE3. In an embodiment, when the light emitting efficiency of the first light emitting element LE1 is lower than the light emitting efficiency of each of the second light emitting element LE2 and the third light emitting element LE3 based on the same size and shape, the size of the first light emitting element LE1 may be larger than the sizes of each of the second light emitting element LE2 and the third light emitting element LE3. Accordingly, the light emitting efficiency of the first light emitting element LE1 may be improved, and a difference in the light emitting efficiency of the first light emitting element LE1, the second light emitting element LE2, and the third light emitting element LE3 may be reduced or prevented.

In another embodiment, the first light emitting element LE1, the second light emitting element LE2, and the third light emitting element LE3 may emit light of the same color as each other. In this case, at least one of a light conversion layer (e.g., a light conversion layer including wavelength conversion particles, such as quantum dots) and/or a color filter may be arranged on the light emitting element LE of at least one of the first sub-pixel SPX1, the second sub-pixel SPX2, and/or the third sub-pixel SPX3 to convert light emitted from the light emitting element LE of the corresponding sub-pixel SPX into light corresponding to an emission color of the corresponding sub-pixel SPX. When the first light emitting element LE1, the second light emitting element LE2, and the third light emitting element LE3 emit light of the same color as each other, the sizes of the first light emitting element LE1, the second light emitting element LE2, and the third light emitting element LE3 may be the same as each other, or may be different from each other. In an embodiment, depending on the light conversion efficiency by the light conversion layer, at least one of the size of the light emitting elements LE of the sub-pixels SPX and/or the area of the light emitting areas EA of the sub-pixels SPX may be differentiated.

Although FIG. 13 illustrates an embodiment in which each of the first sub-pixel SPX1, the second sub-pixel SPX2, and the third sub-pixel SPX3 includes a single light emitting element LE, the present disclosure is not limited thereto. For example, at least one of the first sub-pixel SPX1, the second sub-pixel SPX2, and/or the third sub-pixel SPX3 may include a plurality of light emitting elements LE.

The common electrode CE may be electrically connected to the second power supply lines VSL. For example, the common electrode CE may be electrically connected to the second power supply lines VSL through a cathode contact hole CDH within the display area DA but the present disclosure is not limited thereto. A second driving voltage VSS may be applied to the common electrode CE and the second power supply lines VSL.

The cathode contact hole CDH may be spaced apart from the light emitting elements LE by a suitable distance (e.g., a predetermined distance) or more. In an embodiment, a distance d between the second light emitting element LE2 closest to the cathode contact hole CDH and the cathode contact hole CDH may be approximately 10 µm or more. In an embodiment, the shortest distance d between the cathode contact hole CDH and the light emitting elements LE may be approximately 11 µm in consideration of alignment errors that may occur during a manufacturing process of the display panel 100.

Each light emitting element LE may be more stably arranged in the pixels PX by securing the distance between the cathode contact hole CDH and the light emitting elements LE. For example, by controlling the distance between the cathode contact hole CDH and the light emitting elements LE to 10 µm or more (e.g., 11 µm), the common electrode CE may be flat or substantially flat in the area where the light emitting elements LE are arranged. Accordingly, the light emitting element LE may be stably arranged or bonded on the common electrode CE.

In an embodiment, the distance between the anode contact holes ANH and the light emitting element LE may be greater than or equal to the shortest distance d between the cathode contact hole CDH and the light emitting element LE. Accordingly, the pixel electrodes PXE may be flat or substantially flat in the area where the light emitting elements LE are arranged. Accordingly, the light emitting elements LE may be more stably arranged or bonded on the pixel electrodes PXE and the common electrode CE.

In an embodiment, the common electrode CE may be extended to the non-display area NDA around the display area DA, and may be electrically connected to a power supply bus line (e.g., a bus line to which a second driving voltage VSS is applied) arranged in the non-display area NDA. As the second power supply lines VSL are arranged inside the backplane layer BPL in the display area DA, the resistance of the wiring including the second power supply lines VSL may be reduced.

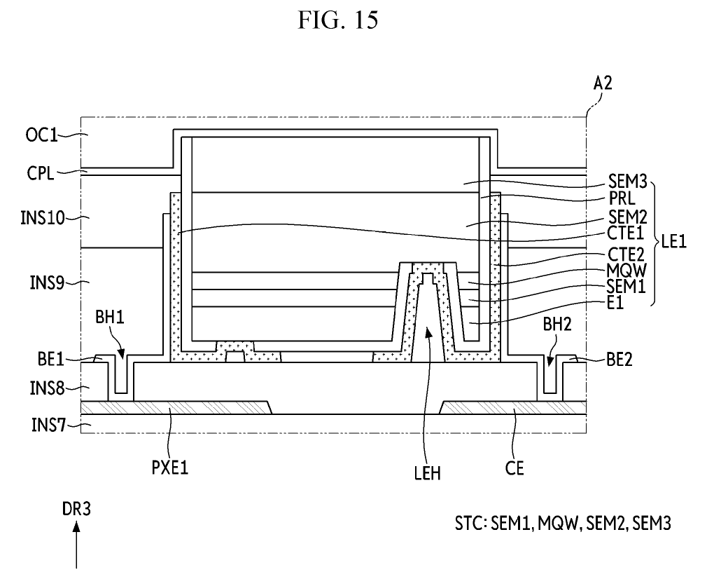

FIG. 14 is a cross-sectional view illustrating an example of a cross-section of a display panel corresponding to the line X1-X1’ of FIG. 13. For example, FIG. 14 illustrates an embodiment of a cross-section of a display panel 100 corresponding to a portion of a first sub-pixel SPX1. In an embodiment, the first sub-pixel SPX1, the second sub-pixel SPX2, and the third sub-pixel SPX3 may have the same or substantially the same (or similar) cross-sectional structures as each other. For example, corresponding circuit elements of the first sub-pixel SPX1, the second sub-pixel SPX2, and the third sub-pixel SPX3 (e.g., the first transistors T1 of the first sub-pixel SPX1, the second sub-pixel SPX2, and the third sub-pixel SPX3) may be arranged in the same layer as each other, and may have the same or substantially the same (or similar) cross-sectional structures as each other.

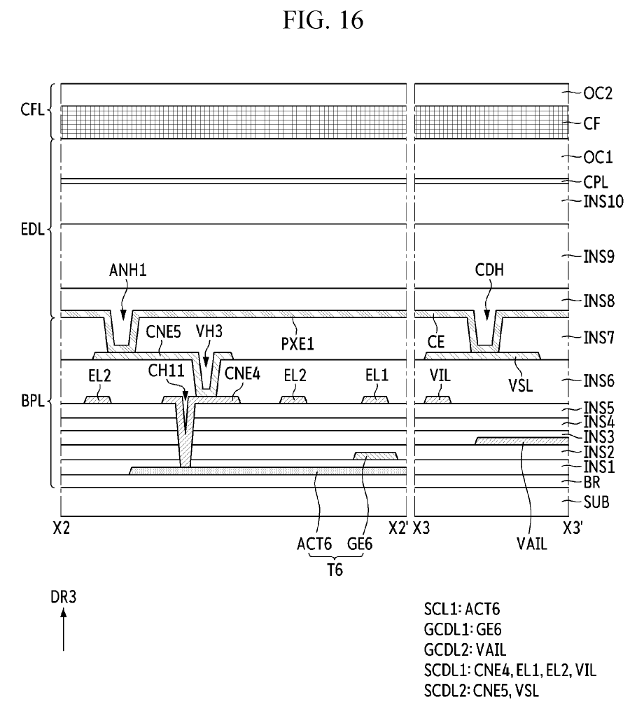

FIG. 15 is a cross-sectional view illustrating the area A2 of FIG. 14 in more detail.

In an embodiment, the first light emitting element LE1, the second light emitting element LE2, and the third light emitting element LE3 may have cross-sectional structures that are the same or substantially the same (or similar) to each other.

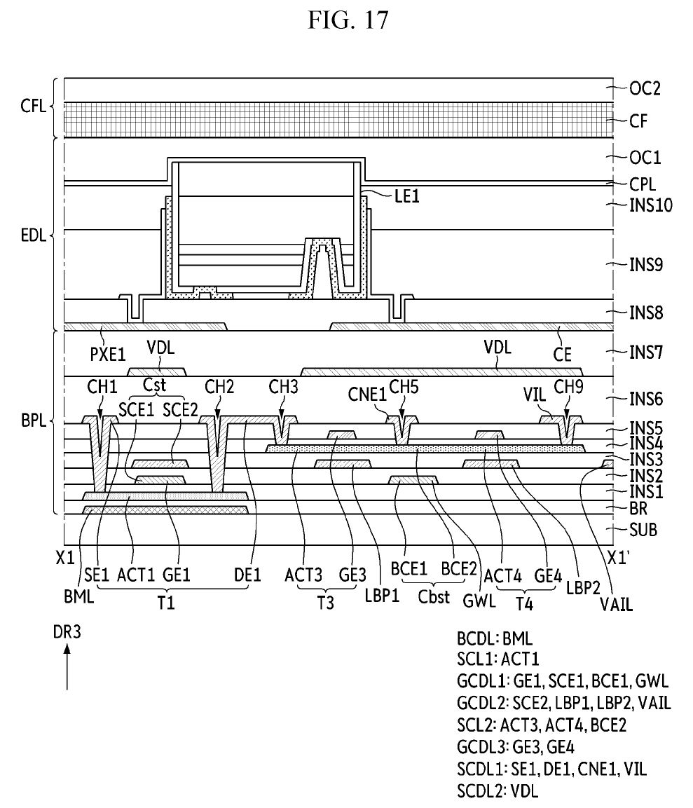

FIG. 16 is a cross-sectional view illustrating an example of a cross-section of a display panel corresponding to the line X2-X2’ and the line X3-X3’ of FIG. 13.

In addition to FIG. 13, referring to FIGS. 14 to 16, the display panel 100 may include a substrate SUB, and a backplane layer BPL and a light emitting element layer EDL arranged on the substrate SUB. In an embodiment, the display panel 100 may further include a color filter layer CFL arranged on the light emitting element layer EDL. The backplane layer BPL, the light emitting element layer EDL, and the color filter layer CFL may be sequentially arranged on the substrate SUB along a third direction DR3.

The substrate SUB may include (e.g., may be made of) an insulating material, such as glass or a polymer resin. When the substrate SUB is made of a polymer resin, it may be a flexible substrate that may be stretched. The polymer resin may be an acrylic resin, an epoxy resin, a phenolic resin, a polyamide resin, or a polyimide resin.

The substrate SUB may include a display area DA and a non-display area NDA. The display area DA may include pixel areas PXA in which pixels PX are arranged. Each pixel area PXA may include light emitting areas EA of sub-pixels SPX.

The backplane layer BPL may include circuit elements included in pixel circuits PXC of sub-pixels SPX, and wirings connected to the sub-pixels SPX. In an embodiment, the backplane layer BPL may be formed entirely on one surface of the substrate SUB.

The backplane layer BPL may include at least one semiconductor layer, conductive layers, and insulating layers. In an embodiment, when the pixel circuits PXC include at least two types of pixel transistors PXT formed of different materials from each other, the backplane layer BPL may include a plurality of semiconductor layers.

For example, the backplane layer BPL may include a barrier layer BR (e.g., a buffer layer), a first semiconductor layer SCL1 (e.g., a polycrystalline silicon semiconductor layer), a first insulating layer INS1 (e.g., a first inorganic insulating layer), a first gate conductive layer GCDL1 (e.g., a first conductive layer), a second insulating layer INS2 (e.g., a second inorganic insulating layer), a second gate conductive layer GCDL2 (e.g., a second conductive layer), a third insulating layer INS3 (e.g., a third inorganic insulating layer), a second semiconductor layer SCL2 (e.g., an oxide semiconductor layer), a fourth insulating layer INS4 (e.g., a fourth inorganic insulating layer), a third gate conductive layer GCDL3 (e.g., a third conductive layer), a fifth insulating layer INS5 (e.g., a fifth inorganic insulating layer), a first source-drain conductive layer SCDL1 (e.g., a fourth conductive layer), a sixth insulating layer INS6 (e.g., a first organic insulating layer), a second source-drain conductive layer SCDL2 (e.g., a fifth conductive layer), and a seventh insulating layer INS7 (e.g., a second organic insulating layer).

The barrier layer BR may be arranged on the substrate SUB. The barrier layer BR may protect the circuit elements of the backplane layer BPL and the light emitting elements LE on the backplane layer BPL from moisture penetrating through the substrate SUB that may be vulnerable to moisture permeation. In an embodiment, the barrier layer BR may be formed of a plurality of inorganic films.

The circuit elements of the backplane layer BPL may be arranged on the barrier layer BR. For example, the pixel transistors PXT, storage capacitors Cst, and boosting capacitors Cbst of the pixel circuits PXC included in each pixel PX may be arranged on the barrier layer BR in each pixel area PXA. Also, the wires of the backplane layer BPL may be arranged on the barrier layer BR. For example, a write scan line GWL, an initialization scan line GIL, a control scan line GCL, a bias scan line GBL, a first light emitting control line EL1, a second light emitting control line EL2, a first data line DLr, a second data line DLg, a third data line DLb, a first power supply line VDL, a second power supply line VSL, a third power supply line VIL, a fourth power supply line VAIL, a fifth power supply line VOBL, and a horizontal power supply line HVDL may be arranged on the barrier layer BR.

In an embodiment, each of the pixel circuits PXC may include first type transistors and second type transistors. The first type transistors and the second type transistors may be arranged in different layers from each other within the backplane layer BPL.

For example, each of the pixel circuits PXC may include first, second, fifth, sixth, seventh and eighth P-type transistors T1, T2, T5, T6, T7, and T8, and third and fourth N-type transistors T3 and T4. The first, second, fifth, sixth, seventh, and eighth active layers ACT1, ACT2, ACT5, ACT6, ACT7, and ACT8 of the first, second, fifth, sixth, seventh, and eighth transistors T1, T2, T5, T6, T7, and T8 and the third and fourth active layers ACT3 and ACT4 of the third and fourth transistors T3 and T4 may be arranged on different semiconductor layers from each other included in the backplane layer BPL. In an embodiment, the first, second, fifth, sixth, seventh, and eighth active layers ACT1, ACT2, ACT5, ACT6, ACT7, and ACT8 of the first, second, fifth, sixth, seventh, and eighth transistors T1, T2, T5, T6, T7, and T8 and the third and fourth active layers ACT3 and ACT4 of the third and fourth transistors T3 and T4 may include, but are not limited to, different semiconductor materials from each other. In addition, the first, second, fifth, sixth, seventh, and eighth gate electrodes GE1, GE2, GE5, GE6, GE7, and GE8 of the first, second, fifth, sixth, seventh, and eighth transistors T1, T2, T5, T6, T7, and T8 and the third and fourth active layers ACT3 and ACT4 of the third and fourth transistors T3 and T4 may be arranged on different conductive layers from each other included in the backplane layer BPL.

In more detail, a first semiconductor layer SCL1 may be arranged on the barrier layer BR. The first semiconductor layer SCL1 may include an active layer of each of the first type transistors. For example, the first semiconductor layer SCL1 may include first, second, fifth, sixth, seventh, and eighth active layers ACT1, ACT2, ACT5, ACT6, ACT7, and ACT8 of first, second, fifth, sixth, seventh, and eighth transistors T1, T2, T5, T6, T7, and T8. FIGS. 14 and 16 illustrate only some of the pixel transistors PXT included in each pixel circuit PXC, and in FIGS. 14 and 16, the first active layer ACT1 and the sixth active layer ACT6 among the active layers included in the first semiconductor layer SCL1 are illustrated. In an embodiment, the first, second, fifth, sixth, seventh, and eighth active layers ACT1, ACT2, ACT5, ACT6, ACT7, and ACT8 of each pixel circuit PXC may be integrally formed with each other using the same semiconductor material. For example, as illustrated in FIGS. 13 to 16, the first, second, fifth, sixth, seventh, and eighth active layers ACT1, ACT2, ACT5, ACT6, ACT7, and ACT8 of each of the first pixel circuit PXC1, the second pixel circuit PXC2, and the third pixel circuit PXC3 may be formed as a single semiconductor pattern that is connected to each other.

The patterns of the first semiconductor layer SCL1 (e.g., the first, second, fifth, sixth, seventh, and eighth active layers ACT1, ACT2, ACT5, ACT6, ACT7, and ACT8) may include the first semiconductor material. In an embodiment, the first semiconductor material may be, but is not limited to, polycrystalline silicon (e.g., a low-temperature polycrystalline silicon). For example, the first semiconductor material may be, but is not limited to, an oxide semiconductor (e.g., at least one of zinc oxide (ZnO), zinc-tin oxide (ZTO), indium-zinc oxide (IZO), indium oxide (InO), titanium oxide (TiO), indium-gallium oxide (IGO), indium-gallium-zinc oxide (IGZO), indium-gallium-tin oxide (IGTO), indium-zinc-tin oxide (IZTO), indium-tin-gallium-zinc oxide (ITGZO), or another oxide semiconductor) or a single-crystalline silicon.

A first insulating layer INS1 may be arranged on the first semiconductor layer SCL1. The first insulating layer INS1 includes at least one insulating material (e.g., silicon nitride (SiNx), silicon oxide (SiOx), silicon oxynitride (SiON), titanium oxide (TiOx), aluminum oxide (AlOx), or other suitable inorganic insulating materials), and may be formed as a single layer or multiple layers.

A first gate conductive layer GCDL1 may be arranged on the first insulating layer INS1. The first gate conductive layer GCDL1 may include a gate electrode of each of the first type transistors. For example, the first gate conductive layer GCDL1 may include first, second, fifth, sixth, seventh, and eighth gate electrodes GE1, GE2, GE5, GE6, GE7, and GE8 of the first, second, fifth, sixth, seventh, and eighth transistors T1, T2, T5, T6, T7, and T8. The first gate conductive layer GCDL1 may further include at least one conductive pattern and/or wiring. For example, the first gate conductive layer GCDL1 may further include a first electrode SCE1 of the storage capacitor Cst, a first electrode BCE1 of the boosting capacitor Cbst, a write scan line GWL, and a bias scan line GBL. In FIGS. 14 and 16, among the patterns of the first gate conductive layer GCDL1, the first gate electrode GE1, the sixth gate electrode GE6, the first electrode SCE1 of the storage capacitor Cst, the first electrode BCE1 of the boosting capacitor Cbst, and the write scan line GWL are illustrated.

In an embodiment, the first gate electrode GE1 of each pixel circuit PXC and the first electrode SCE1 of the storage capacitor Cst may be formed integrally with each other, and the second gate electrode GE2, the first electrode BCE1 of the boosting capacitor Cbst, and the write scan line GWL (e.g., the write scan line GWL connected to the sub-pixels SPX of the corresponding horizontal line) may be formed integrally with each other. Also, the seventh gate electrode GE7, the eighth gate electrode GE8, and the bias scan line GBL (e.g., the bias scan line GBL connected to the sub-pixels SPX of the corresponding horizontal line) may be formed integrally with each other.

The patterns of the first gate conductive layer GCDL1 (e.g., the first, second, fifth, sixth, seventh, and eighth gate electrodes GE1, GE2, GE5, GE6, GE7, and GE8, the first electrode SCE1 of the storage capacitor Cst, the first electrode BCE1 of the boosting capacitor Cbst, the write scan line GWL, and the bias scan line GBL) may include the same conductive material as each other.

A second insulating layer INS2 may be arranged on the first gate conductive layer GCDL1. The second insulating layer INS2 may include at least one insulating material (e.g., an inorganic insulating material), and may be formed as a single layer or multiple layers.

A second gate conductive layer GCDL2 may be arranged on the second insulating layer INS2. The second gate conductive layer GCDL2 may include the second electrode SCE2 of the storage capacitor Cst. The first electrode SCE1 and the second electrode SCE2 of the storage capacitor Cst may be stacked with the first insulating layer INS1 between them. The second electrode SCE2 of the storage capacitor Cst may be opened at a portion where the first electrode SCE1 of the storage capacitor Cst is connected to the first connection electrode CNE1 (e.g., the fourth contact hole CH4 and its surroundings). The second gate conductive layer GCDL2 may further include at least one conductive pattern and/or wiring. For example, the second gate conductive layer GCDL2 may further include a first blocking pattern LBP1, a second blocking pattern LBP2, a horizontal power supply line HVDL, and a fourth power supply line VAIL. In FIGS. 14 and 16, among the patterns of the second gate conductive layer GCDL2, the second electrode SCE2 of the storage capacitor Cst, the first light blocking pattern LBP1, the second light blocking pattern LBP2, and the fourth power supply line VAIL are illustrated.

In an embodiment, the first light blocking pattern LBP1 of the sub-pixels SPX arranged in each horizontal line may be formed integrally with each other, and the second light blocking pattern LBP2 of the sub-pixels SPX arranged in each horizontal line may be formed integrally with each other. Also, the second electrodes SCE2 of the storage capacitors Cst of the sub-pixels SPX arranged in each horizontal line and the horizontal power supply line HVDL may be formed integrally with each other.

The patterns of the second gate conductive layer GCDL2 (e.g., the second electrode SCE2 of the storage capacitor Cst, the first light blocking pattern LBP1, the second light blocking pattern LBP2, the horizontal power supply line HVDL, and the fourth power supply line VAIL) may include the same conductive material as each other.

A third insulating layer INS3 may be arranged on the second gate conductive layer GCDL2. The third insulating layer INS3 may include at least one insulating material (e.g., an inorganic insulating material), and may be formed as a single layer or multiple layers.

A second semiconductor layer SCL2 may be arranged on the third insulating layer INS3. The second semiconductor layer SCL2 may include an active layer of each of the second type transistors. Also, the second semiconductor layer SCL2 may include the third and fourth active layers ACT3 and ACT4 of the third and fourth transistors T3 and T4. In an embodiment, the third and fourth active layers ACT3 and ACT4 of each pixel circuit PXC may be integrally formed with each other using the same semiconductor material.

The patterns of the second semiconductor layer SCL2 (e.g., the third and fourth active layers ACT3 and ACT4, and the second electrode BCE2 of the boosting capacitor Cbst) may include a second semiconductor material. In an embodiment, the second semiconductor material may be an oxide semiconductor, but the present disclosure is not limited thereto. For example, the second semiconductor material may be polycrystalline silicon or a single-crystal silicon.

A fourth insulating layer INS4 may be arranged on the second semiconductor layer SCL2. The fourth insulating layer INS4 may include at least one insulating material (e.g., an inorganic insulating material), and may be formed as a single layer or multiple layers.

A third gate conductive layer GCDL3 may be arranged on the fourth insulating layer INS4. The third gate conductive layer GCDL3 may include the gate electrodes of each of the second type transistors. For example, the third gate conductive layer GCDL3 may include the third and fourth gate electrodes GE3 and GE4 of the third and fourth transistors T3 and T4. The third gate conductive layer GCDL3 may further include at least one conductive pattern and/or wiring. For example, the third gate conductive layer GCDL3 may further include an initialization scan line GIL, a control scan line GCL, and a fifth power supply line VOBL. In FIGS. 14 and 16, the third gate electrode GE3 and the fourth gate electrode GE4 among the patterns of the third gate conductive layer GCDL3 are illustrated.

In an embodiment, the third gate electrode GE3 and the control scan line GCL (e.g., the control scan line GCL connected to the sub-pixels SPX of the corresponding horizontal line) may be formed integrally with each other. Also, the fourth gate electrode GE4 and the initialization scan line GIL (e.g., the initialization scan line GIL connected to the sub-pixels SPX of the corresponding horizontal line) may be formed integrally with each other.

The patterns of the third gate conductive layer GCDL3 (e.g., the third and fourth gate electrodes GE3 and GE4, the initialization scan line GIL, the control scan line GCL, and the fifth power supply line VOBL) may include the same conductive material as each other.

A fifth insulating layer INS5 may be arranged on the third gate conductive layer GCDL3. The fifth insulating layer INS5 includes at least one insulating material (e.g., an inorganic insulating material), and may be formed as a single layer or multiple layers.

A first source-drain conductive layer SCDL1 may be arranged on the fifth insulating layer INS5. The first source-drain conductive layer SCDL1 may include at least one electrode, a conductive pattern, and/or a wiring. For example, the first source-drain conductive layer SCDL1 may include source and drain electrodes SE1 and DE1 of the first transistor T1, first, second, third, fourth, sixth, and seventh connection electrodes CNE1, CNE2, CNE3, CNE4, CNE6, and CNE7, first and second light emitting control lines EL1 and EL2, and a third power supply line VIL. In FIGS. 14 and 16, among the patterns of the first source-drain conductive layer SCDL1, the source and drain electrodes SE1 and DE1 of the first transistor T1, the first and fourth connection electrodes CNE1 and CNE4, the first and second light emitting control lines EL1 and EL2, and the third power supply line VIL are illustrated.

The patterns of the first source-drain conductive layer SCDL1 (e.g., the source and drain electrodes SE1 and DE1 of the first transistor T1, the first, second, third, fourth, sixth, and seventh connection electrodes CNE1, CNE2, CNE3, CNE4, CNE6, and CNE7, the first and second light emitting control lines EL1 and EL2, and the third power supply line VIL) may include the same conductive material as each other.

A sixth insulating layer INS6 may be arranged on the first source-drain conductive layer SCDL1. The sixth insulating layer INS6 may include at least one insulating material (e.g., an acrylic resin, an epoxy resin, a phenolic resin, a polyamide resin, a polyimide resin, or other organic insulating materials), and may be formed as a single layer or multiple layers. A second source-drain conductive layer SCDL2 may be arranged on the sixth insulating layer INS6.

The second source-drain conductive layer SCDL2 may include at least one electrode, a conductive pattern, and/or a wiring. For example, the second source-drain conductive layer SCDL2 may include a fifth connection electrode CNE5, first, second, and third data lines DLr, DLg, and DLb, and first and second power supply lines VDL and VSL. In FIGS. 14 and 16, the fifth connection electrode CNE5, the first power supply line VDL, and the second power supply line VSL among the patterns of the second source-drain conductive layer SCDL2 are illustrated.

The patterns of the second source-drain conductive layer SCDL2 (e.g., the fifth connection electrode CNE5, the first, second, and third data lines DLr, DLg, and DLb, and the first and second power supply lines VDL and VSL) may include the same conductive material as each other.

A seventh insulating layer INS7 may be arranged on the second source-drain conductive layer SCDL2. The seventh insulating layer INS7 may include at least one insulating material (e.g., an organic insulating material), and may be formed as a single layer or multiple layers.

The patterns included in each of the conductive layers of the backplane layer BPL may include at least one conductive material. For example, the electrodes, conductive patterns, and/or wirings included in each of the first gate conductive layer GCDL1, the second gate conductive layer GCDL2, the third gate conductive layer GCDL3, the first source-drain conductive layer SCDL1, and the second source-drain conductive layer SCDL2 may include at least one of copper (Cu), titanium (Ti), molybdenum (Mo), aluminum (Al), chromium (Cr), gold (Au), silver (Ag), platinum (Pt), palladium (Pd), nickel (Ni), neodymium (Nd), iridium (Ir), tantalum (Ta), tungsten (W), magnesium (Mg), other suitable metals, suitable alloys thereof, or other conductive materials. In an embodiment, the electrodes, conductive patterns, and/or wirings arranged on the same conductive layer as each other may be concurrently (e.g., simultaneously or substantially simultaneously) formed with each other using the same conductive material. At least two of the conductive layers of the backplane layer BPL may include the same conductive material as each other, or may include different conductive materials from each other.

In an embodiment, the patterns included in each of the conductive layers of the backplane layer BPL may have a single-layer or multi-layered structure. For example, each of the electrodes, conductive patterns, and/or wirings included in each of the first gate conductive layer GCDL1, the second gate conductive layer GCDL2, the third gate conductive layer GCDL3, the first source-drain conductive layer SCDL1, and the second source-drain conductive layer SCDL2 may have a single-layer or multi-layered structure. At least two of the conductive layers of the backplane layer BPL may have the same cross-sectional structure as each other, or may have different cross-sectional structures from each other.

In an embodiment, the patterns of the second source-drain conductive layer SCDL2 may include a metal (e.g., at least one of molybdenum (Mo), aluminum (Al), chromium (Cr), gold (Au), titanium (Ti), nickel (Ni), neodymium (Nd), copper (Cu) other metals, or an alloy thereof), and may have a single-layer or multi-layered structure. For example, the electrodes, conductive patterns, and/or wirings included in the second source-drain conductive layer SCDL2 may be low-resistance patterns formed with a triple-layered structure of titanium/aluminum/titanium (Ti/Al/Ti). As another example, the patterns of the second source-drain conductive layer SCDL2 may include other low-resistance materials and/or structures. When the resistance of the patterns included in the second source-drain conductive layer SCDL2 is reduced or minimized, the resistance of the first power supply line VDL and the second power supply line VSL through which the driving current Ids of each of the sub-pixels SPX flows may be reduced or minimized. Accordingly, the image quality of the display device 10 may be uniformized, and a power consumption may be improved.

The light emitting element layer EDL may be arranged on the seventh insulating layer INS7. The light emitting element layer EDL may include pixel electrodes PXE, light emitting elements LE, and a common electrode CE included in the sub-pixels SPX. Also, the light emitting element layer EDL may further include insulating layers. In an embodiment, the insulating layers of the light emitting element layer EDL may include eighth, ninth, and tenth insulating layers INS8, INS9, and INS10, a capping layer CPL, and a first overcoat layer OC1.

A pixel electrode layer including pixel electrodes PXE of sub-pixels SPX may be arranged on the seventh insulating layer INS7. For example, the pixel electrode layer may include a first pixel electrode PXE1, a second pixel electrode PXE2, and a third pixel electrode PXE3. In an embodiment, the light emitting element LE may be a flip-chip kind of micro LED. The flip-chip kind of micro LED refers to an LED in which first and second contact electrodes CTE1 and CTE2 are formed on one surface (e.g., a bottom surface) of the light emitting element LE. When the light emitting element LE is a flip-chip kind of micro LED, the pixel electrode layer may further include a common electrode CE. For example, the pixel electrodes PXE and the common electrode CE of the sub-pixels SPX may be arranged on the same layer as each other, and may be formed concurrently (e.g., simultaneously or substantially simultaneously) with each other using the same conductive material.

A first pixel electrode PXE1 of the first sub-pixel SPX1 may be electrically connected to a fifth connection electrode CNE5 of the first sub-pixel SPX1 through a first anode contact hole ANH1 (e.g., a contact hole that penetrates the seventh insulating layer INS7 to expose the fifth connection electrode CNE5 of the first sub-pixel SPX1). A second pixel electrode PXE2 of the second sub-pixel SPX2 may be electrically connected to a fifth connection electrode CNE5 of the second sub-pixel SPX2 through a second anode contact hole ANH2 (e.g., a contact hole that penetrates the seventh insulating layer INS7 to expose the fifth connection electrode CNE5 of the second sub-pixel SPX2. The third pixel electrode PXE3 of the third sub-pixel SPX3 may be electrically connected to the fifth connection electrode CNE5 of the third sub-pixel SPX3 through the third anode contact hole ANH3 (e.g., a contact hole that penetrates the seventh insulating layer INS7 to expose the fifth connection electrode CNE5 of the third sub-pixel SPX3). Accordingly, the first pixel electrode PXE1, the second pixel electrode PXE2, and the third pixel electrode PXE3 are electrically connected to the first pixel circuit PXC1, the second pixel circuit PXC2, and the third pixel circuit PXC3, respectively, and the first pixel circuit PXC1, the second pixel circuit PXC2, and the third pixel circuit PXC3 may control voltages applied to the first pixel electrode PXE1, the second pixel electrode PXE2, and the third pixel electrode PXE3.

The common electrode CE shared by the first, second, and third sub-pixels SPX1, SPX2, and SPX3 may be electrically connected to the second power supply line VSL of the backplane layer BPL through a cathode contact hole CDH (e.g., a contact hole that penetrates the seventh insulating layer INS7 to expose the second power supply line VSL of the backplane layer BPL). Accordingly, the second driving voltage VSS applied to the second power supply line VSL may be transmitted to the common electrode CE.

In an embodiment, the patterns of the pixel electrode layer (e.g., the pixel electrodes PXE and the common electrode CE) may include the same conductive material as each other. In an embodiment, the patterns of the pixel electrode layer (e.g., the pixel electrodes PXE and the common electrode CE) may include the same conductive material as each other. In an embodiment, the patterns of the pixel electrode layer include a metal (e.g., at least one of molybdenum (Mo), aluminum (Al), chromium (Cr), gold (Au), titanium (Ti), nickel (Ni), neodymium (Nd), copper (Cu), other metals, or an alloy thereof), and may have a single-layer or multi-layered structure. For example, the patterns of the pixel electrode layer may be low-resistance patterns formed with a triple-layered structure of titanium/aluminum/titanium (Ti/Al/Ti). As another example, the patterns of the pixel electrode layer may include other low-resistance materials (e.g., copper (Cu)) and/or structures. When the resistance of the patterns included in the pixel electrode layer is reduced or minimized, the first driving voltage VDD and the second driving voltage VSS may be stably transmitted to the light emitting elements LE of the sub-pixels SPX.

An eighth insulating layer INS8 may be arranged on the pixel electrodes PXE and the common electrode CE. The eighth insulating layer INS8 temporarily fixes or adheres the light emitting elements LE to prevent the light emitting elements LE from tilting and falling over during a process of transferring the light emitting elements LE to the display panel 100. For example, the eighth insulating layer INS8 may be a film for temporarily adhering the light emitting elements LE onto each of the pixel electrodes PXE and the common electrode CE. To facilitate the temporary adhesion, the thickness of the eighth insulating layer INS8 may be greater than the thickness of each of the pixel electrodes PXE and the common electrode CE, and may be greater than the thickness of each of the first and second contact electrodes CTE1 and CTE2 of the light emitting elements LE.

In FIGS. 14 to 16, the eighth insulating layer INS8 is illustrated as being arranged over the entire display area DA, but the present disclosure is not limited thereto. For example, the eighth insulating layer INS8 may be arranged only on a portion of the pixel electrodes PXE and the common electrode CE that overlap the light emitting elements LE and may expose other portions of the pixel electrodes PXE and the common electrode CE.

The eighth insulating layer INS8 may include at least one insulating material, for example, an organic insulating material. For example, the eighth insulating layer INS8 may be a photosensitive organic film such as a photoresist. As another example, the eighth insulating layer INS8 may be formed of an acrylic resin, an epoxy resin, a phenolic resin, a polyamide resin, or a polyimide resin.

The light emitting elements LE may be arranged on the eighth insulating layer INS8. For example, a first light emitting element LE1 may be arranged on the first pixel electrode PXE1 and the common electrode CE of the first sub-pixel SPX1. A second light emitting element LE2 may be arranged on the second pixel electrode PXE2 and the common electrode CE of the second sub-pixel SPX2. A third light emitting element LE3 may be arranged on the third pixel electrode PXE3 and the common electrode CE of the third sub-pixel SPX3.

In an embodiment, each of the light emitting elements LE may be a micro LED including an inorganic material. For example, each of the light emitting elements LE may be formed of an inorganic material, such as gallium nitride (GaN), and a length of each of the light emitting elements LE in the first direction DR1, a length of each of the second direction DR2, and a length of each of the light emitting elements LE in the third direction DR3 may each be several µm to several hundred µm. For example, each of the length of each of the light emitting elements LE in the first direction DR1, the length of each of the second direction DR2, and the length of each of the third direction DR3 may be approximately 100 µm or less.

The light emitting elements LE may be grown and formed on a semiconductor substrate, such as a silicon substrate or a sapphire substrate. The light emitting elements LE may be transferred directly from the semiconductor substrate onto the pixel electrodes PXE and the common electrode CE of the display panel 100. As another example, the light emitting elements LE may be transferred onto the pixel electrodes PXE and the common electrode CE of the display panel 100 by an electrostatic method using an electrostatic head or a stamp method using an elastic polymer material such as PDMS or silicon as a transfer substrate.

The light emitting element LE may include a conductive layer E1, a semiconductor stack STC, contact electrodes CTE1 and CTE2, and a protective layer PRL. The semiconductor stack STC may include a first semiconductor layer SEM1, an active layer MQW (e.g., an emitting layer), and a second semiconductor layer SEM2 sequentially arranged in a third direction DR3. In an embodiment, the semiconductor stack STC may further include a third semiconductor layer SEM3 on the second semiconductor layer SEM2.

The conductive layer E1 may be arranged on the bottom surface of the first semiconductor layer SEM1. In FIG. 15, the conductive layer E1 is illustrated as covering the entire bottom surface of the first semiconductor layer SEM1, but the present disclosure is not limited thereto. For example, the conductive layer E1 may be arranged on a portion of the bottom surface of the first semiconductor layer SEM1. The conductive layer E1 may include one of molybdenum (Mo), aluminum (Al), chromium (Cr), gold (Au), titanium (Ti), nickel (Ni), neodymium (Nd), copper (Cu), or a transparent conductive material, such as a metal oxide.

The first semiconductor layer SEM1 may be arranged on the conductive layer E1. The first semiconductor layer SEM1 may be formed of a semiconductor material layer doped with a first conductive dopant, such as magnesium (Mg), zinc (Zn), calcium (Ca), strontium (Sr), barium (Ba), and/or the like, for example, gallium nitride (GaN).

The active layer MQW may be arranged on the first semiconductor layer SEM1. The active layer MQW may include the same semiconductor material as the those of first semiconductor layer SEM1 and the second semiconductor layer SEM2. For example, when the first semiconductor layer SEM1 and the second semiconductor layer SEM2 include gallium nitride (GaN), the active layer MQW may also include gallium nitride (GaN). For example, the active layer MQW may include at least one of gallium nitride (GaN), indium gallium nitride (InGaN), and/or aluminum gallium nitride (AlGaN). The active layer MQW may emit light by recombination of electron-hole pairs in response to an electric signal applied through the first semiconductor layer SEM1 and the second semiconductor layer SEM2.

The active layer MQW may include a suitable material having a single or multi-quantum well structure. When the active layer MQW includes a material having a multi-quantum well structure, it may have a structure in which a plurality of well layers and barrier layers are alternately stacked. The well layer may be formed of indium gallium nitride (InGaN), and the barrier layer may be formed of gallium nitride (GaN) or aluminum gallium nitride (AlGaN), but the present disclosure is not limited thereto. As another example, the active layer MQW may have a structure in which semiconductor materials having a high band gap energy and semiconductor materials having a low band gap energy are alternately stacked with each other, or may include other Group three to five semiconductor materials according to the wavelength range of emitted light.

When the active layer MQW includes indium gallium nitride (InGaN), the color of the emitted light may vary depending on the content of indium (In). For example, as the content of indium (In) increases, the wavelength band of light emitted by the active layer may shift to the red wavelength band, and as the content of indium (In) decreases, the wavelength band of light emitted by the active layer may shift to the blue wavelength band. For example, the content of indium (In) in the active layer MQW of the light emitting element LE that emits the third light (blue light) may be approximately 10 wt% to 20 wt%.

The second semiconductor layer SEM2 may be arranged on the active layer MQW. The second semiconductor layer SEM2 may be a semiconductor material layer doped with a second conductivity type dopant, such as silicon (Si), germanium (Ge), tin (Sn), and/or the like, for example, gallium nitride (GaN).

The third semiconductor layer SEM3 may be arranged on the second semiconductor layer SEM2. The third semiconductor layer SEM3 may be a semiconductor material layer having an n-type dopant lower than a threshold value (e.g., a predetermined threshold value), and may be referred to as an undoped semiconductor layer. For example, the third semiconductor layer SEM3 may be indium aluminum gallium nitride (InAlGaN), gallium nitride (GaN), aluminum gallium nitride (AlGaN), indium gallium nitride (InGaN), aluminum nitride (AlN), or indium nitride (InN) having an n-type dopant lower than a threshold value (e.g., a predetermined threshold value).

An electron blocking layer may be arranged between the first semiconductor layer SEM1 and the active layer MQW. The electron blocking layer may be a layer to suppress or prevent too many electrons from flowing into the active layer MQW. For example, the electron blocking layer may be aluminum gallium nitride (AlGaN) or a p-type aluminum gallium nitride (AlGaN) doped with p-type magnesium (Mg). The electronic blocking layer may be omitted as needed or desired.

A superlattice layer may be arranged between the active layer MQW and the second semiconductor layer SEM2. The superlattice layer may be a layer for relieving stress between the second semiconductor layer SEM2 and the active layer MQW. For example, the superlattice layer may be aluminum gallium nitride (AlGaN) or a p-type aluminum gallium nitride (AlGaN) doped with a p-type magnesium (Mg). The superlattice layer may be omitted as need or desired.

A protective film PRL may be arranged on a side surface of the first semiconductor layer SEM1, a side surface of the active layer MQW, and a side surface of the second semiconductor layer SEM2. The protective film PRL may be a film for protecting a side surface of the light emitting element LE. The protective film PRL may be formed of an inorganic material, such as silicon nitride (SiNₓ), silicon oxide nitride (SiON), silicon oxide (SiOₓ), titanium oxide (TiOₓ), aluminum oxide (AlOₓ), or another inorganic insulating material.

In FIG. 15, the protective film PRL is illustrated as being arranged on the side surfaces of the first semiconductor layer SEM1, the side surfaces of the active layer MQW, and the side surfaces of the second semiconductor layer SEM2 of the semiconductor stack STC, but not arranged on the side surfaces of the third semiconductor layer SEM3. However, the present disclosure is not limited thereto. For example, the protective film PRL may be arranged on the side surfaces of the first semiconductor layer SEM1, the side surfaces of the active layer MQW, the side surfaces of the second semiconductor layer SEM2, and the side surfaces of the third semiconductor layer SEM3 of the semiconductor stack STC.

A hole LEH may be formed that penetrates the conductive layer E1, the first semiconductor layer SEM1, and the active layer MQW of the light emitting element LE to expose the second semiconductor layer SEM2. The hole LEH may have a circular planar shape, but the present disclosure is not limited thereto. For example, the hole LEH may have another planar shape, such as an ellipse or a polygon such as a square.

The protective film PRL may be arranged on the sidewall of the conductive layer E1 exposed in the hole LEH, the sidewall of the first semiconductor layer SEM1, and the sidewall of the active layer MQW. The protective film PRL may not cover the second semiconductor layer SEM2 in the hole LEH. Accordingly, the second semiconductor layer SEM2 may be exposed without being covered by the protective film PRL.

The first contact electrode CTE1 may be arranged on at least one side surface of the semiconductor stack STC, and at least one side surface and the bottom surface of the conductive layer E1. The first contact electrode CTE1 may be arranged on the bottom surface of the conductive layer E1 exposed without being covered by the protective film PRL. Therefore, the first contact electrode CTE1 may be electrically connected to the conductive layer E1.

The second contact electrode CTE2 may be arranged on at least one side of the semiconductor stack STC, and at least one side and the bottom surface of the conductive layer E1. The first contact electrode CTE1 may be arranged on the first side of the semiconductor stack STC and the first side of the conductive layer E1, while the second contact electrode CTE2 may be arranged on the second side of the semiconductor stack STC and the second side of the conductive layer E1.

The second contact electrode CTE2 may be arranged on the protective film PRL arranged in the hole LEH, and on the second semiconductor layer SEM2 exposed without being covered by the protective film PRL in the hole LEH. Therefore, the second contact electrode CTE2 may be electrically connected to the second semiconductor layer SEM2 in the hole LEH.

Although FIGS. 14 and 15 illustrate that the first contact electrode CTE1 and the second contact electrode CTE2 of each of the light emitting elements LE are arranged on the eighth insulating layer INS8, the present disclosure is not limited thereto. For example, the eighth insulating layer INS8 may be arranged on a portion of the bottom surface and the side surface of the first contact electrode CTE1 of each of the light emitting elements LE, and on a portion of the bottom surface and the side surface of the second contact electrode CTE2. As another example, the eighth insulating layer INS8 may be arranged on the side surfaces of the conductive layer E1 of each of the light emitting elements LE. As another example, the eighth insulating layer INS8 may be arranged on the side surfaces of the first semiconductor layer SEM1, the side surfaces of the active layer MQW, and the side surfaces of the second semiconductor layer SEM2 of each of the light emitting elements LE. In this case, the eighth insulating layer INS8 may be arranged on a portion of each of the side surfaces of the second semiconductor layer SEM2.

Each of the first contact electrode CTE1 and the second contact electrode CTE2 may be arranged on three side surfaces of the semiconductor stack STC. For example, when the semiconductor stack STC includes first to fourth side surfaces, the first contact electrode CTE1 may be arranged on the first side, the second side, and the third side, and the second contact electrode CTE2 may be arranged on the second side, the third side, and the fourth side.

Each of the first contact electrode CTE1 and the second contact electrode CTE2 may include at least one conductive material, for example, such as one of molybdenum (Mo), aluminum (Al), chromium (Cr), gold (Au), titanium (Ti), nickel (Ni), neodymium (Nd), and/or copper (Cu). In an embodiment, the first contact electrode CTE1 and the second contact electrode CTE2 may be formed as a two-layered structure of chromium (Cr) and gold (Au), a three-layered structure of titanium (Ti), aluminum (Al), and titanium (Ti), or a three-layered structure of indium tin oxide (ITO), silver (Ag), and indium tin oxide (ITO), to increase a reflectivity.

When each of the first contact electrode CTE1 and the second contact electrode CTE2 is formed of a metal having a high reflectivity, light emitted from the active layer MQW of the light emitting element LE and traveling in the lateral direction of the light emitting element LE may be reflected by the first contact electrode CTE1 and the second contact electrode CTE2, and may be emitted to the top surface of the light emitting element LE. Therefore, because the loss of light from the light emitting element LE may be reduced, the light efficiency of the light emitting element LE may be increased. To increase the light efficiency of the light emitting element LE, the first contact electrode CTE1 and the second contact electrode CTE2 may be arranged to cover most of the side surfaces of the semiconductor stack STC.

The first bridge electrode BE1 (e.g., the eighth connection electrode) connects the first contact electrode CTE1 of the light emitting element LE and a corresponding one of each pixel electrode PXE to each other. For example, the first bridge electrode BE1 of the first sub-pixel SPX1 may connect the first contact electrode CTE1 of the first light emitting element LE1 and the first pixel electrode PXE1 to each other. The first bridge electrode BE1 of the second sub-pixel SPX2 may connect the first contact electrode CTE1 of the second light emitting element LE2 and the second pixel electrode PXE2 to each other, and the first bridge electrode BE1 of the third sub-pixel SPX3 may connect the first contact electrode CTE1 of the third light emitting element LE3 and the third pixel electrode PXE3 to each other.

The first bridge electrode BE1 may be connected to a corresponding one of each pixel electrode PXE exposed through the first connection hole BH1 penetrating the eighth insulating layer INS8. Further, the first bridge electrode BE1 may be arranged on the top surface of the eighth insulating layer INS8 and the first contact electrode CTE1 of the light emitting element LE. In another embodiment, if (e.g., when) the eighth insulating layer INS8 is arranged only on a portion of the pixel electrode PXE overlapping with the light emitting element LE, the first connection hole BH1 may be unnecessary. For example, the first bridge electrode BE1 may be arranged directly on the pixel electrode PXE exposed around the light emitting element LE.

The second bridge electrode BE2 (e.g., the ninth connection electrode) connects the second contact electrode CTE2 of the light emitting element LE and the common electrode CE to each other. For example, the second bridge electrode BE2 of the first sub-pixel SPX1 may connect the second contact electrode CTE2 of the first light emitting element LE1 and the common electrode CE to each other. The second bridge electrode BE2 of the second sub-pixel SPX2 may connect the second contact electrode CTE2 of the second light emitting element LE2 and the common electrode CE to each other, and the second bridge electrode BE2 of the third sub-pixel SPX3 may connect the second contact electrode CTE2 of the third light emitting element LE3 and the common electrode CE to each other. In another embodiment, if (e.g., when) the eighth insulating layer INS8 is arranged only on a portion of the common electrode CE overlapping with the light emitting element LE, the second connection hole BH2 may be unnecessary. For example, the second bridge electrode BE2 may be arranged directly on the common electrode CE exposed around the light emitting element LE.

The second bridge electrode BE2 may be connected to the common electrode CE exposed through the second connection hole BH2 penetrating the eighth insulating layer INS8. Additionally, the second bridge electrode BE2 may be arranged on the top surface of the eighth insulating layer INS8 and the second contact electrode CTE2.

Each of the first bridge electrode BE1 and the second bridge electrode BE2 may include at least one conductive material, for example, such as one of molybdenum (Mo), aluminum (Al), chromium (Cr), gold (Au), titanium (Ti), nickel (Ni), neodymium (Nd), and/or copper (Cu). As another example, each of the first bridge electrode BE1 and the second bridge electrode BE2 may be made of a transparent conductive material (e.g., a transparent conductive oxide (TCO)), such as indium tin oxide (ITO) and/or indium zinc oxide (IZO).

When each of the first bridge electrode BE1 and the second bridge electrode BE2 is made of a metal material having a high reflectivity, such as aluminum (Al), light emitted from the active layer MQW of the light emitting element LE and traveling in the lateral direction of the light emitting element LE may be reflected by the connection electrodes BE, and may travel in the upward direction of the light emitting element LE. Accordingly, because the light loss of the light emitting element LE may be reduced, the light efficiency of the light emitting element LE may be increased.

As shown in FIGS. 14 and 15, the conductive layer E1 of the light emitting element LE may be electrically connected to a corresponding one of each pixel electrode PXE through the first contact electrode CTE1 and the first bridge electrode BE1. Further, the second semiconductor layer SEM2 of the light emitting element LE may be electrically connected to the common electrode CE through the second contact electrode CTE2 and the second bridge electrode BE2 formed in the hole LEH. The pixel electrodes PXE may be referred to as an anode electrode or a first electrode, and the common electrode CE may be referred to as a cathode electrode or a second electrode.

The ninth insulating layer INS9 may be arranged on the eighth insulating layer INS8. The ninth insulating layer INS9 may be arranged to cover a portion of the side surface of the light emitting elements LE. Further, the ninth insulating layer INS9 may be arranged to cover the first and second bridge electrodes BE1 and BE2, but at least a portion of the first and second bridge electrodes BE1 and BE2 may be exposed without being covered by the ninth insulating layer INS9.

The tenth insulating layer INS10 may be arranged on the ninth insulating layer INS9. The tenth insulating layer INS10 may be arranged to cover a portion of a side surface of each of the light emitting elements LE. The tenth insulating layer INS10 may be arranged on at least a portion of the first and second bridge electrodes BE1 and BE2 that are exposed without being covered by the ninth insulating layer INS9. The top surface of each of the light emitting elements LE may be exposed without being covered by the tenth insulating layer INS10.

The ninth insulating layer INS9 and the tenth insulating layer INS10 may include at least one insulating material, for example, such as an organic insulating material. For example, each of the ninth insulating layer INS9 and the tenth insulating layer INS10 may be formed of an organic film, such as an acrylic resin, an epoxy resin, a phenolic resin, a polyamide resin, a polyimide resin, or the like.

The ninth insulating layer INS9 and the tenth insulating layer INS10 may flatten a step caused by the light emitting elements LE. When the height of the ninth insulating layer INS9 is arranged to cover most of the side surfaces of each of the light emitting elements LE, the tenth insulating layer INS10 may be omitted.

The capping layer CPL may be arranged on the light emitting elements LE, the ninth insulating layer INS9, and the tenth insulating layer INS10. The capping layer CPL may include at least one insulating material, for example, such as an inorganic insulating material.

In an embodiment, if (e.g., when) the light emitting elements LE of each of the sub-pixels SPX emit light of a color corresponding to (e.g., matching) the emission color (e.g., the emission wavelength) of the corresponding sub-pixel SPX, the display panel 100 may not include a light conversion layer. For example, the first overcoat layer OC1 may be arranged directly on the capping layer CPL.

When the sub-pixels SPX include light emitting elements LE that emit light corresponding to their respective emission colors, the light emitted from the light emitting elements LE may be utilized more efficiently. For example, the light efficiency of the sub-pixels SPX may be prevented from decreasing due to a light conversion. Furthermore, the color purity of the light emitted from the sub-pixels SPX may be increased, and the color reproducibility of the sub-pixels SPX may be increased.

In another embodiment, when the light emitting element LE of at least one sub-pixel SPX emits light of a different color from that of the emission color (e.g., the emission wavelength) of the corresponding sub-pixel SPX, a light conversion layer may be further arranged on the light emitting element LE. For example, when the first light emitting element LE1 emits blue light and the first sub-pixel SPX1 is a red sub-pixel that emits red light, a light conversion layer covering the first light emitting element LE1 may be arranged on the capping layer CPL. The light conversion layer may include light conversion particles (e.g., red quantum dots and/or the like) that convert blue light incident from the first light emitting element LE1 into red light. When the sub-pixels SPX include light emitting elements LE that emit light of the same color as each other, the manufacturing efficiency of the light emitting element layer EDL and the display panel 100 including the light emitting element layer EDL may be increased, and manufacturing costs may be reduced.

The first overcoat layer OC1 may be arranged on the capping layer CPL (or the light conversion layer). The first overcoat layer OC1 may be an organic film including an organic insulating material (e.g., an acrylic resin, an epoxy resin, a phenolic resin, a polyamide resin, or a polyimide resin), and the top surface of the first overcoat layer OC1 may be flat or substantially flat. However, the present disclosure is not limited thereto. For example, the first overcoat layer OC1 may be an inorganic film including an inorganic insulating material, and the first overcoat layer OC1 may be formed to a sufficient thickness to include a flat or substantially flat top surface, or may be flattened through a separate flattening process. Accordingly, the top surface of the first overcoat layer OC1 may be flat or substantially flat.

A color filter layer CFL may be arranged on the first overcoat layer OC1. The color filter layer CFL may further include color filters CF arranged in the light emitting areas EA of the sub-pixels SPX, and a second overcoat layer OC2 covering the color filters CF.

The color filter layer CFL may include color filters CF that selectively transmit light corresponding to the emission color (e.g., the emission wavelength) of each of the sub-pixels SPX. For example, when the first sub-pixel SPX1, the second sub-pixel SPX2, and the third sub-pixel SPX3 emit red light, green light, and blue light, respectively, a red color filter, a green color filter, and a blue color filter may be arranged in the first light emitting area EA1 of the first sub-pixel SPX1, the second light emitting area EA2 of the second sub-pixel SPX2, and the third light emitting area EA3 of the third sub-pixel SPX3, respectively. In an embodiment, the color filters CF of the sub-pixels SPX may overlap with each other in a non-emission area surrounding (e.g., around peripheries of) the light emitting areas EA of the sub-pixels SPX to form a light blocking pattern.

The second overcoat layer OC2 may be arranged on the color filters CF. The second overcoat layer OC2 may be an organic film including an organic insulating material, and the top surface of the second overcoat layer OC2 may be flat or substantially flat. However, the present disclosure is not limited thereto. For example, the second overcoat layer OC2 may be an inorganic film including an inorganic insulating material, and the second overcoat layer OC2 may be formed to a sufficient thickness to include a flat or substantially flat top surface, or may be flattened through a separate flattening process. Accordingly, the top surface of the second overcoat layer OC2 may be flat or substantially flat.

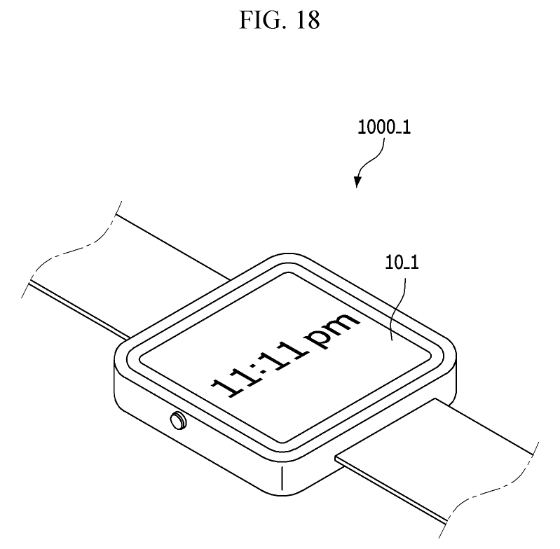

FIG. 17 is a cross-sectional view illustrating an example of a cross-section of a display panel corresponding to the line X1-X1’ of FIG. 13. For example, FIG. 17 illustrates an embodiment of a cross-section of a display panel 100 corresponding to a portion of a first sub-pixel SPX1. Compared to the embodiment illustrated in FIG. 14, FIG. 17 illustrates an embodiment in which the display panel 100 further includes a bottom conductive layer BCDL.

Referring to FIG. 17, the display panel 100 may further include the bottom conductive layer BCDL arranged on a substrate SUB. For example, the backplane layer BPL may include the bottom conductive layer BCDL arranged between the substrate SUB and the barrier layer BR.

The bottom conductive layer BCDL may include a bottom pattern BML arranged under the first transistor T1. The bottom pattern BML may completely or partially cover a bottom surface of the first active layer ACT1. For example, the bottom pattern BML may be arranged below the first active layer ACT1 to overlap with the channel region of the first active layer ACT1 (e.g., a portion of the first active layer ACT1 that overlaps with the first gate electrode GE1).

In an embodiment, the bottom conductive layer BCDL may include a light blocking material. For example, the bottom conductive layer BCDL may include a metal, and the bottom pattern BML may be formed as a lower metal pattern. In an embodiment, the bottom pattern BML may be electrically connected to a power line to which a constant voltage is applied (e.g., the first power supply line VDL). In an embodiment, the bottom pattern BML may be formed in the display area DA as a pattern that extends or is connected along at least one of the first direction DR1 and/or the second direction DR2 when viewed on a plane defined by the first direction DR1 and the second direction DR2 (e.g., in a plan view), but the present disclosure is not limited thereto.

The bottom pattern BML may block external light from entering the channel region of the first active layer ACT1 from the lower portion of the first transistor T1. Furthermore, the bottom pattern BML may distribute charges that may gather around the first transistor T1. Accordingly, the operating characteristics of the first transistor T1 may be stabilized.

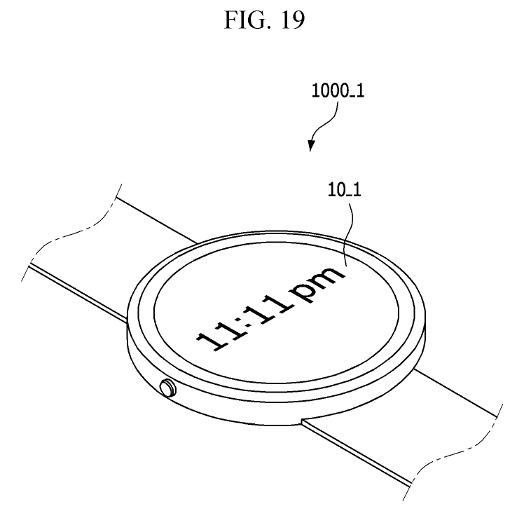

FIGS. 18 and 19 illustrate a smart watch including a display device according to an embodiment.

Referring to FIGS. 18 and 19, a display device 10_1 according to an embodiment may be applied to a smart watch 1000_1, which is one of smart devices.

The flat shape of the display device 10_1 may be a square or a circle but the present disclosure is not limited thereto and may be modified in various ways, such as an oval.

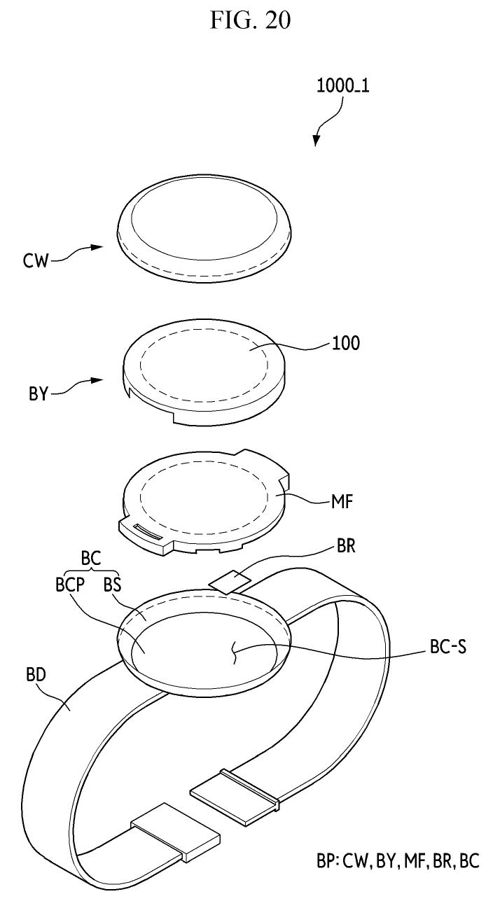

FIG. 20 is an exploded perspective view of a smart watch including a display device according to an embodiment.

Referring to FIG. 20, the smart watch 1000_1 may include a main body unit BP and a wearable portion BD.

The main body unit BP may include a display panel 100 on which an image is displayed, a cover window CW disposed on the display panel 100, a bottom cover BC disposed under the display panel 100, a middle frame MF disposed between the cover window CW and the bottom cover BC, and a battery BR disposed between the middle frame MF and the bottom cover BC. In addition to the battery BR, a main processor controlling the smart watch 1000_1, a communication chipset for wirelessly communicating with the outside, and a circuit board in which memory, etc. are mounted may be additionally arranged between the middle frame MF and the bottom cover BC.

The main body unit BP may sequentially include a bottom cover BC, a battery BR, a middle frame MF, a display panel 100, and a cover window CW.

The cover window CW is arranged on the upper portion of the display panel 10 to protect the display panel 10 and to transmit light emitted from the display panel 10. As described above, the cover window CW may include a light-blocking portion to block a portion of the light emitted from the display panel 10. The cover window CW may be made of a transparent plastic material, a glass material, or a reinforced glass material.

The cover window CW may be arranged to overlap the display panel 10 and cover the front of the display panel 10. The cover window CW generally has a shape similar to that of the display panel 10 in terms of a plane, but its size may be larger than that of the display panel 10. For example, the cover window CW may protrude outward from the display panel 10. The plane shape of the cover window CW may be the same as that of the main body unit BP. For example, the planar shape of the cover window CW may be generally circular but the present disclosure is not limited thereto and may have various shapes, for example, a polygon such as a square or an oval.

The middle frame MF is a joining member for joining the cover window CW and the bottom cover BC and is arranged between the cover window CW and the bottom cover BC. For example, the middle frame MF may include a bracket.

The bottom cover BC is a housing arranged under the display panel 10.

The bottom cover BC may include a central cover portion BCP and a peripheral portion BS arranged around the central cover portion BCP.

The central cover portion BCP is located at the center of the bottom cover BC and may be generally flat.

The peripheral portion BS may be arranged to surround the central cover portion BCP. The peripheral portion BS may be a portion that is bent and curved from the central cover portion BCP. The peripheral portion BS may be bent from the edge of the central portion CP. In some embodiments, the peripheral portion BS may include a curved surface having a predetermined curvature, and the other portion may be flat. The degree (e.g., angle) at which the peripheral portion BS is bent from the central cover portion BCP may be an obtuse angle, but the present disclosure is not limited thereto, and may also be a right angle or an acute angle.

A storage space BC-S may be formed by the central cover portion BCP and the peripheral portion BS. A battery BR may be placed in the storage space BC-S.

The battery BR may be connected to a circuit board on which a main processor or the like is mounted. The display device 10_1 may be electrically connected to the circuit board to receive digital video signals, timing signals, power, and the like.

The bottom cover BC is placed on the outermost rear surface of the electronic device and may include at least one of a plastic material, a metal material, and a glass material, and may include a color coating layer. For example, the bottom cover BC according to one example may be a flat glass having a transparent, translucent, or opaque color coating layer.

The bottom cover BC according to another example may have the same shape as the cover window CW and may include a glass material having a color coating layer. For example, the bottom cover BC according to another example may have a structure symmetrical to the cover window CW with a middle frame MF in between and may include a transparent, translucent, or opaque color coating layer.

The wearing portion BD is a portion for fixing the main body unit BP to the user's wrist, for example, and may be one of a strap, a chain, and a bracelet.

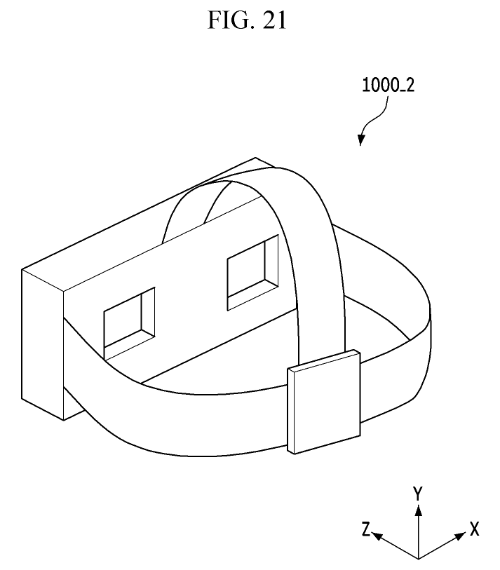

FIG. 21 illustrates a virtual reality (VR) device including a display device according to an embodiment.

Referring to FIG. 21, a head mounted display device 1000_2 according to one or more embodiments include a display device housing 1100, a housing cover 1200, a first eyepiece 1210, a second eyepiece 1220, and head mounted band 1300.

The display device housing 1100 houses a display device. a head mounted display device 1000_2 according to one or more embodiments further include a first optical member disposed between the first display device 10_2 and the first eyepiece 1210.

The housing cover 1200 is placed to cover an open surface of the display device housing 1100. The housing cover 1200 may include the first eyepiece 1210 on which a user’s left eye is placed and the second eyepiece 1220 on which the user’s right eye is placed. Although the first eyepiece 1210 and the second eyepiece 1220 are disposed separately in FIGS. 30, the present disclosure is not limited thereto. The first eyepiece 1210 and the second eyepiece 1220 may also be combined into one.

The head mounted band 1300 fixes the display device housing 1100 to a user’s head so that the first eyepiece 1210 and the second eyepiece 1220 of the housing cover 1200 are kept placed on the user’s left and right eyes, respectively. When the display device housing 1200 is implemented to be lightweight and small, the head mounted display device 1000_2 may include an eyeglass frame as illustrated in FIG. 35 instead of the head mounted band 1300.

The display device housing 1100 houses display device. In addition, the head mounted display device 1000_2 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

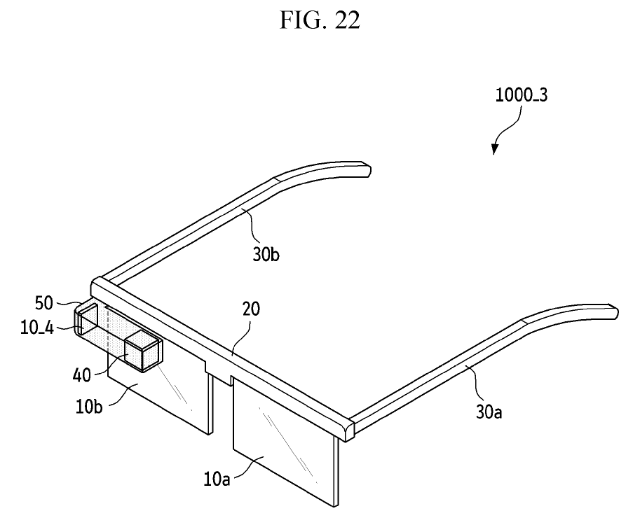

FIG. 22 illustrates a head-mounted display device including a display device according to an embodiment. FIG. 22 illustrates a VR device 1000_3 to which a display device 10_4 according to one or more embodiments has been applied.

Referring to FIG. 22, the VR device 1000_3 according to one or more embodiments may be a device in the form of glasses. The VR device 1000_3 according to the embodiment may include the display device 10_4, a left lens 10a, a right lens 10b, a support frame 20, eyeglass frame legs 30a and 30b, a reflective member 40, and a display device housing 50.

In FIG. 22, a case where the VR device 1000_3 is a glasses-type display device including the eyeglass frame legs 30a and 30b is illustrated as an example. In other words, the VR device 1000_3 according to the embodiment is not limited to the one illustrated in FIG. 31 and can be applied in various forms to various other electronic devices.

The display device housing 50 may include the display device 10_4 and the reflective member 40. An image displayed on the display device 10_4 may be reflected by the reflective member 40 and provided to a user’s right eye through the right lens 10b. Accordingly, the user may view a VR image displayed on the display device 10_4 through the right eye.

Although the display device housing 50 is disposed at a right end of the support frame 20 in FIG. 22, the present disclosure is not limited thereto. For example, the display device housing 50 may also be disposed at a left end of the support frame 20. In this case, an image displayed on the display device 10_4 may be reflected by the reflective member 40 and provided to the user’s left eye through the left lens 10a. Accordingly, the user may view a VR image displayed on the display device 10_4 through the left eye. As another example, the display device housing 50 may be disposed at both the right end and the left end of the support frame 20. In this case, the user may view a VR image displayed on the display device 10_4 through both the left eye and the right eye.

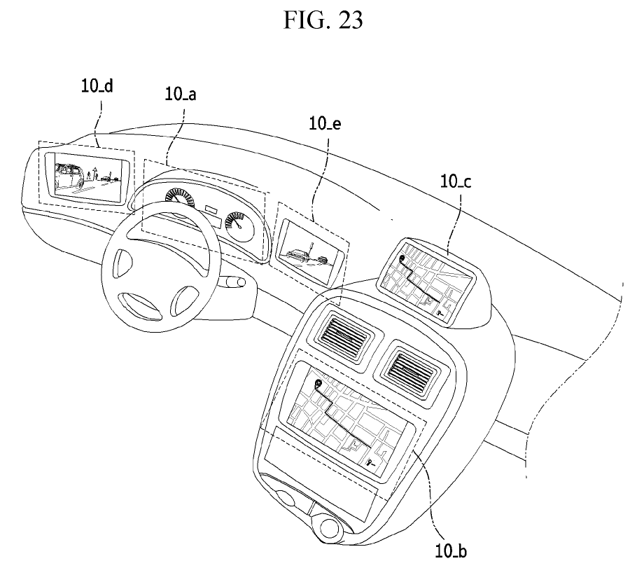

FIG. 23 illustrates an automobile instrument panel and center fascia including display devices according to an embodiment. FIG. 23 illustrates a vehicle to which display devices 10_a through 10_e according to one or more embodiments have been applied.

Referring to FIG. 23, the display devices 10_a through 10_c according to the embodiment may be applied to an instrument cluster of the vehicle, a center fascia of the vehicle, or a center information display (CID) disposed on a dashboard of the vehicle. In addition, the display devices 10_d and 10_e according to the embodiment may be applied to room mirror displays that replace side mirrors of the vehicle.

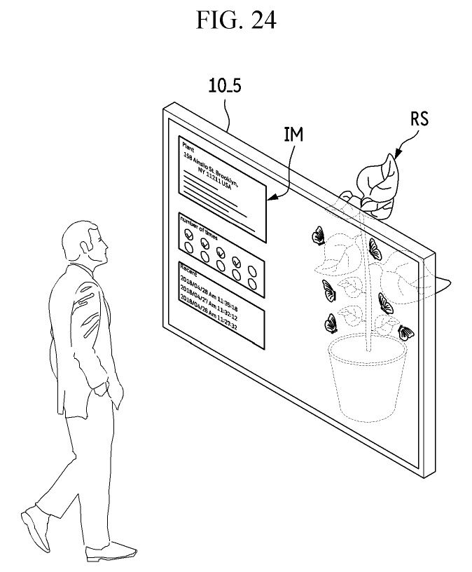

FIG. 24 illustrates a transparent display device including a display device according to an embodiment.

Referring to FIG. 24, a display device 10_5 according to one or more embodiments may be applied to a transparent display device. The transparent display device may transmit light while displaying an image IM. Therefore, a user located in front of the transparent display device cannot only view the image IM displayed on the display device 10_5 but also view an object RS or the background located behind the transparent display device. When the display device 10_5 is applied to the transparent display device, a substrate of the display device 10_5 may include a light transmitting portion that can transmit light or may be made of a material that can transmit light.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a display panel comprising a display area, a non-display area, and a plurality of pixels in the display area;
a light emitting driving portion configured to apply light emitting control signals to the plurality of pixels, and located in the non-display area on a first side of the display area; and
a scan driving portion configured to apply scan signals to the display panel, and located in the non-display area on a second side opposite to the first side of the display area,
wherein the plurality of pixels comprises:
a first sub-pixel configured to emit light of a first wavelength; and
a second sub-pixel configured to emit light of a second wavelength shorter than the first wavelength, and
wherein the light emitting driving portion comprises:
a first light emitting driver configured to apply a first light emitting control signal to the first sub-pixel; and
a second light emitting driver configured to apply a second light emitting control signal to the second sub-pixel.

2. The display device of claim 1, wherein the scan driving portion comprises a write scan signal driver, an initialization scan signal and control scan signal driver, and a bias scan signal driver, each connected to a sub-pixel from among the first and second sub-pixels, and configured to apply a scan signal.

3. The display device of claim 2, wherein the non-display area surrounds around the display area, and the first side and the second side have a symmetrical shape with each other.

4. The display device of claim 2, wherein the write scan signal driver, the initialization scan signal and control scan signal driver, and the bias scan signal driver are located in order of a decreasing size closer to the display area.

5. The display device of claim 4, wherein the write scan signal driver, the initialization scan signal and control scan signal driver, and the bias scan signal driver are located in order closer to the display area.

6. The display device of claim 1, wherein the light emitting driver and the scan driver are symmetrical with each other about the display area.

7. The display device of claim 4 further comprising:
a first light emitting control line connecting the first light emitting driver and the first sub-pixel to each other; and
a second light emitting control line connecting the second light emitting driver and the second sub-pixel to each other.

8. The display device of claim 2 further comprising:
a write scan line connecting the write scan signal driver to the first sub-pixel and the second sub-pixel;
a control scan line connecting the initialization scan signal and control scan signal driver to the first sub-pixel and the second sub-pixel;
an initialization scan line connecting the initialization scan signal and control scan signal driver to the first sub-pixel and the second sub-pixel; and
a bias scan line connecting the bias scan signal driver to the first sub-pixel and the second sub-pixel.

9. The display device of claim 2, wherein the plurality of pixels further comprises a third sub-pixel configured to emit light of a third wavelength shorter than the light of the first wavelength, and
wherein the second light emitting driver is configured to apply the second light emitting control signal to the third sub-pixel.

10. The display device of claim 9, wherein the second light emitting control line further connects the second light emitting driver and the third sub-pixel to each other,
wherein the write scan line further connects the write scan signal driver and the third sub-pixel to each other,
wherein the control scan line further connects the initialization scan signal and control scan signal driver and the third sub-pixel to each other,
wherein the initialization scan line further connects the initialization scan signal and control scan signal driver and the third sub-pixel to each other, and
wherein the bias scan line further connects the bias scan signal driver and the third sub-pixel to each other.

11. The display device of claim 3, wherein the display area has a square or circular shape.

12. The display device of claim 9, wherein the first sub-pixel comprises a first pixel circuit, and a first light emitting element electrically connected to the first pixel circuit,
wherein the second sub-pixel comprises a second pixel circuit, and a second light emitting element electrically connected to the second pixel circuit, and
wherein the third sub-pixel comprises a third pixel circuit, and a third light emitting element electrically connected to the third pixel circuit.

13. A display device comprising:
a display panel comprising a display area, a non-display area, and a first sub-pixel and a second sub-pixel in the display area;
a light emitting driving portion comprising a first light emitting driver configured to apply a first light emitting control signal to the first sub-pixel, and a second light emitting driver configured to apply a second light emitting control signal to the second sub-pixel; and
a scan driving portion comprising a write scan signal driver, an initialization scan signal and control scan signal driver, and a bias scan signal driver, each connected to the first sub-pixel and the second sub-pixel, and configured to apply a scan signal,
wherein the light emitting driver and the scan driver are symmetrically located in the non-display area with the display panel therebetween.

14. The display device of 13, wherein the write scan signal driver, the initialization scan signal and control scan signal driver, and the bias scan signal driver are located in order closer to the display area.

15. The display device of 13 further comprising:
a first light emitting control line connecting the first light emitting driver and the first sub-pixel to each other; and
a second light emitting control line connecting the second light emitting driver and the second sub-pixel to each other.

16. The display device of claim 13 further comprising:
a write scan line connecting the write scan signal driver to the first sub-pixel and the second sub-pixel;
a control scan line connecting the initialization scan signal and control scan signal driver to the first sub-pixel and the second sub-pixel;
an initialization scan line connecting the initialization scan signal and control scan signal driver to the first sub-pixel and the second sub-pixel; and
a bias scan line connecting the bias scan signal driver to the first sub-pixel and the second sub-pixel.

17. The display device of 15, wherein the first light emitting control line extends in a first direction in the display area, and is electrically connected to the first sub-pixel, and
wherein the second light emitting control line extends in the first direction in the display area, and is electrically connected to the second sub-pixel.

18. The display device of 13, wherein the first sub-pixel comprises a first light emitting element configured to emit light of a first wavelength, and
wherein the second sub-pixel comprises a second light emitting element configured to emit light of a second wavelength shorter than the first wavelength.

19. An electronic device comprising:
a display device;
a window on the display device; and
a bottom cover under the display device,
wherein the display device comprises:
a display panel comprising a display area, a non-display area, and a plurality of pixels in the display area;
a light emitting driving portion configured to output light emitting control signals to the display panel, and located in the non-display area on a second side opposite to a first side of the display area; and
a scan driving portion configured to output scan signals to the display panel, and located in the non-display area on the first side of the display area,
wherein the plurality of pixels comprises a first sub-pixel configured to emit light of a first wavelength, and a second sub-pixel configured to emit light of a second wavelength shorter than the first wavelength, and
wherein the light emitting driving portion comprises a first light emitting driver configured to apply a first light emitting control signal to the first sub-pixel, and a second light emitting driver configured to apply a second light emitting control signal to the second sub-pixel.

20. The electronic device of claim 19, further comprising:
a battery located in a space of the bottom cover, and configured to supply power to the display device; and
a middle frame between the window and the bottom cover.
